(19) United States
(12) Patent Application Publication
(10) Pub. No.: US 2011/0310530 A1
(43) Pub. Date: Dec. 22, 2011

(54) SINTERED AND NANOPORE ELECTRIC CAPACITOR, ELECTROCHEMICAL CAPACITOR AND BATTERY AND METHOD OF MAKING THE SAME

(75) Inventor: Herzel Laor, Boulder, CO (US)

(73) Assignee: LAOR CONSULTING LLC, Denver, CO (US)

(21) Appl. No.: 13/148,918

(22) PCT Filed: Feb. 11, 2010
(86) PCT No.: PCT/US10/23848

§ 371 Date: Aug. 10, 2011

Related U.S. Application Data
(63) Continuation of application No. 12/370,394, filed on Feb. 12, 2009.
(60) Provisional application No. 61/028,383, filed on Feb. 13, 2008.
(60) Provisional application No. 61/028,402, filed on Feb. 13, 2008.
(60) Provisional application No. 61/262,851, filed on Nov. 19, 2009.
(60) Provisional application No. 61/259,550, filed on Nov. 9, 2009.

(51) Int. Cl. H01G 4/06; H05K 13/00

(52) U.S. Cl. 361/524; 29/592.1

(57) ABSTRACT

The present invention relates generally to the field of sequential surface chemistry. More specifically, it relates to products and methods for manufacturing products using Atomic Layer Deposition (“ALD”) to depose one or more materials onto a surface. ALD has the capability for high-quality defect free film deposition with few molecular layers. The present invention includes, in varying embodiments, methods of manufacturing electric components such as batteries, capacitors and electrochemical capacitors by ALD, and the products manufactured by those methods.

### CROSS REFERENCE TO RELATED APPLICATIONS

The present application claims the benefit of U.S. patent application Ser. No. 12/370,394, filed Feb. 12, 2009, which claims the benefit of U.S. Provisional Patent Application Nos. 61/028,383 and 61/028,402, both filed Feb. 13, 2008, all of which are incorporated herein by reference in their entirety. The present application also claims the benefit of U.S. Provisional Patent Application Nos. 61/259,550, filed Nov. 9, 2009, and 61/262,851, filed Nov. 19, 2009, both of which are incorporated herein by reference in their entirety.

### BACKGROUND

The present invention relates generally to the field of sequential surface chemistry. More specifically, it relates to products and methods for manufacturing products using Atomic Layer Deposition (“ALD”) to depose one or more materials onto a surface. ALD is a thin film deposition technique based on the sequential use of a gas phase chemical process. ALD has capability for high-quality, molecular-scale film depositions. ALD is used for about 40 years now, see U.S. Pat. No. 4,058,430 to Suntola et al., U.S. Pat. No. 4,413,022 to Suntola, et al.,

http://en.wikipedia.org/wiki/Atomic_Layer_Deposition and http://www.colorado.edu/chemistry/GeorgeResearchGroup/intro/IntroALD.pdf for details related to ALD technology, the contents of all of which are incorporated herein by reference in their entirety. ALD manufacturing technology is developed to a high level, with deposition equipment available from several companies. See, e.g. www.picosun.com, www.beneq.com, www.oxford-instruments.com, www.cambridgenanotech.com, www.sundewtech.com, all of which are incorporated herein by reference in their entirety.

The Chemical Vapor deposition (“CVD”) process is useful in forming material layers on a substrate surface, such as an electrode. However, the non-uniformity of the layers deposited on the substrate can lead to voids and thickness variations, thereby rendering the electrode or other electrical component inoperable. In addition, while CVD coats the exposed surface of the substrate, ALD is penetrating, and will coat conformal, equal thickness layers on both exposed and hidden surfaces, due to the self-limiting properties of the ALD process. Characteristics similar to those of CVD are present for evaporation coating and sputtering. Some of these characteristics can be used as benefits where a coating is required only on exposed surfaces.

Current technology for capacitors with high specific capacity (defined herein as Microfarad times Volts per cubic millimeter) are Aluminum and Tantalum electrolytic capacitors, See http://en.wikipedia.org/wiki/Electrolytic_capacitor. For example, the size of a 10 V, 10 μF, Tantalum electrolytic capacitor for surface mount application is approximately 2*2*3.5 mm³. The specific capacity of such electrolytic capacitor is 7.1 VμF/mm³, and it will have about 1 μA leakage current after approximately 2 minutes of applying the rated voltage. Tan δ is 0.06. This electrolytic capacitor should endure approximately 2000 hours at 85° C. and at the rated voltage. In short, electrolytic capacitors has severe limitation is their application due to short life (especially at elevated temperatures), high series resistance, energy losses due to ripple current that results in heating, inability to be used in AC applications, damaging failure mode (spreading of conductive electrolyte), limited operational temperature range, high leakage current, capacitance dependent on how long the capacitor was under applied voltage, etc.

Attempts has been made to construct a capacitor deposited by ALD on anodic Al with nanopores. See: “Nanotubular metal-insulator-metal capacitor arrays for energy storage”, Parag Banerjee et al, Nature Nanotechnology, VOL 4, May 2009, p. 292 which is included herein in its entirety. However, such designs lack an enabling solution to connect this component to electric wiring with reasonably low resistance.

ALD-manufactured gates and capacitors in semiconductor applications demonstrates the benefits over other known manufacturing methods. Some ALD films are exceptionally defect free, stress free and pinhole free down to the 1-2 molecular layers. This unmatched characteristic is useful for the deposition of gate and capacitor dielectrics, diffusion-barriers and seed layers. For a general discussion see:

http://www.semiconductor.net/article/279085-IMEC_Tips_{—}10_nm_Options_at_Tech_Forum.php,
http://www.semiconductor.net/article/206893-ALD_PVD_Barrier_Reduces_RC_and_Improves_Reliability.php,
http://www.semiconductor.net/article/358034-High_Power_Transistors_Emerge_at_CEATEC.php and “Needs for Next Generation Memory and Enabling Solutions Based on Advanced Vaporizer ALD Technology”, Zia Karim et al. Proceedings of the 9th International Conference on Atomic Layer deposition, July 2009, Monterey, Calif., USA, p. 57, all of which are incorporated herein by reference in their entirety.

Electrochemical capacitors (also known as electric double-layer capacitors or supercapacitors) are used when large capacitance is needed, leveraging the flow of ions in a cell to store electric charge.

Electrochemical capacitors have a high number of charge-discharge cycles, typically in the millions, can have fast charge-discharge time, but can store less energy then batteries.

Electric batteries utilizes chemical compositions to store energy. See, for example, “Batteries and electrochemical capacitors”, Hector D. Abruiio et al, Physics Today, December 2008 p. 43 and “Solid-state microscale lithium batteries prepared with microfabrication processes”, Jie Song et al. 2009 J. Micromech. Microeng. 19 045004 (6 pp), all of which are incorporated herein by reference in their entirety.

The term “battery” as used herein will generally refer to an electric battery unless otherwise specified. Chemical reactions generate a flow of ions in the battery and electrical current flow out of the battery. Some batteries (secondary cells) can be charged by applying current that causes the flow of ions and the storage of energy in chemical bonds. Most batteries have a limitation in that the number of charge-discharge cycles is limited to no more than a few thousand cycles, charge-discharge time is relatively slow and most batteries develop heat during operation.

There has been a substantial amount of research for materials applicable as the anode, cathode, electrolyte and separator for batteries. In advanced designs, one material is used as both the electrolyte and separator, called fast ion conductor, solid electrolyte or superionic conductor. The term “solid electrolyte” will be used herein.

There is, however, still a need for an improved method of manufacturing electronic components such as batteries, capacitors, electrochemical capacitors and other components that overcomes the foregoing problems and also produces components that are more efficient due to a decreased size, better performance parameters and improved reliability. Various embodiments of the present invention address these needs.

### SUMMARY

In one embodiment of the present invention, an electrical component is provided that is comprised of:

a first electrode formed of sintered structure made of metallic particles that is mostly un-oxidized with less than a 100% fill ratio;

a dielectric layer, formed by ALD, wherein the dielectric layer substantially surrounds the first electrode;

insulator formed on an exposed surface of the sintered structure;

a second electrode formed in the remaining volume to fully or partially complement the first electrode and the dielectric layer; and

first and second terminals disposed in electrical connection with the sintered structure and the second electrode respectively.

These sintered capacitors will have fully monolithic structure, no leakage, low serial resistance and inductance, long life at elevated temperatures, induce no damage to the surrounding electronics upon failure and will be capable of full AC operation. The sintered capacitors manufactured according to this embodiment have a specific capacity, by way of example but not limitation, of 25 VμF/mm³-3.5 times higher then Tantalum capacitors, and 35 times higher then Aluminum capacitors.

According to yet another embodiment, an electrochemical capacitor or battery is provided as in the previous embodiment but with the dielectric replaced by anode material, cathode material and solid electrolyte material. These electrochemical capacitors and batteries will have improved performance compared with conventional electrochemical capacitors or batteries, mainly due to the fact the the distance that ions need to travel between cathode and anode is in the nanometer scale compared with millimeters or tenth of millimeters in conventional such components.

According to yet another embodiment, an electrochemical capacitor or battery is provided as in the previous embodiment but with the second electrode is omitted and either the cathode or the anode, whichever is further from the first electrode, will carry the electrical current to the second terminal.

According to another embodiment of the present invention, a method of manufacturing of an electrical component is provided, the method comprising:

providing a first electrode formed of sintered structure made of metallic particles with less than a 100% fill ratio that is mostly un-oxidized;

soldering, brazing or connecting by other technology a first terminal to the sintered structure to create mechanical and electrical connection between the first terminal and the first electrode;

depositing, via ALD, dielectric layer wherein the dielectric layer substantially surrounds the first electrode;

installing an insulator formed on an exposed surface of the structure (note that this step and the previous step can be reversed);

providing a second electrode formed in part or all of the remaining volume to complement the first electrode and the dielectric layer; and

soldering, brazing or connecting by other technology a second terminal disposed in electrical connection with the second electrode.

According to yet another embodiment, a method of manufacturing electrochemical capacitor or battery is provided as in the previous embodiment but with the step of depositing dielectric replaced by steps of depositing, via ALD, anode material, solid electrolyte material and cathode material, in this order or the reversed order, and the step of installing an insulator is performed either before or after the step of depositing the solid electrolyte.

According to yet another embodiment, a method of manufacturing electrochemical capacitor or battery is provided as in the previous embodiment but with the step of depositing the second electrode is omitted and either the cathode or the anode, whichever is further from the first electrode, will carry the electrical current to the second terminal.

According to yet another embodiment, a capacitor is provided having:

a scaffolding having a plurality of pores therein where at least one pore transverses the scaffolding from a first facet to a second facet;

a first conductor deposed on the surface of the scaffolding including on the inner surface of the plurality of pores;

a first electrically conductive surface at the first facet in electrical contact with the first conductor;

a first terminal brazed or soldered to the first electrically conductive surface;

a dielectric deposed on the surface of the first conductor including on the inner surface of the plurality of pores;

an insulator installed on an exposed surface of the scaffolding;

a second conductor deposed on the surface of the dielectric including on the inner surface of the plurality of pores;

a second electrically conductive surface at the second facet, the second electrically conductive surface is in electrical contact with the second conductor; and

a second terminal brazed or soldered to the second electrically conductive surface;

According to yet another embodiment, electrochemical capacitor or battery is provided as in the previous embodiment but with the dielectric replaced by anode material, solid electrolyte material and cathode material.

According to yet another embodiment, electrochemical capacitor or battery is provided as in the previous embodiment but with the first conductor and the second conductor are omitted, and the anode and cathode carry electrical current to the first electrically conductive surface and the second electrically conductive surface respectively or to the second electrically conductive surface and the first electrically conductive surface, respectively.

According to yet another embodiment, a method of manufacturing a capacitor is provided, the method comprising:

providing a scaffolding having a plurality of pores therein where at least one pore transverses the scaffolding from a first facet to a second facet;

depositing, via ALD, a first conductor on the surface of the scaffolding including on the inner surface of the plurality of pores;

establishing, via CVD, evaporating coating, sputtering or another technology, generally on the first facet of the scaffolding but generally not in the pores, a first electrically conductive surface in electrical contact with the conductor;

brazing or soldering a first terminal to the first electrically conductive surface;

depositing, via ALD, a dielectric on the surface of the first conductor including on the inner surface of the plurality of pores;

installing an insulator on an exposed surface of the scaffolding (note that this step and the previous step can be swapped with the same performance of the final component);

depositing, via ALD, a second conductor on the surface of the dielectric including on the inner surface of the plurality of pores;

establishing, via CVD, evaporating coating, sputtering or another technology a second electrically conductive surface at the second facet, the second electrically conductive surface is in electrical contact with the second conductor; and

brazing or soldering a second terminal to the second electrically conductive surface;

According to yet another embodiment, a method of manufacturing electrochemical capacitor or battery is provided as in the previous embodiment but with the step of depositing an dielectric replaced by steps of depositing, via ALD, anode material, solid electrolyte material and cathode material, in this order or in the reverse order. The step of installing an insulator will be performed before or after the step of deposing the solid electrolyte.

According to yet another embodiment, a method of manufacturing electrochemical capacitor or battery is provided as in the previous embodiment but with the step of depositing, via ALD, a first conductor and the step of depositing, via ALD, a second conductor are omitted.

According to yet another embodiment, an electrical component is provided, comprising:

a pored scaffolding having a plurality of pores and where at least one pore transverses the scaffolding from a first facet to a second facet;

two or more layers of conductive material deposited on the scaffolding and substantially covering all surfaces of the pores within the scaffolding, where the two layers of conductive material are not in direct electrical contact with each other;

a first contact disposed on the first facet;

a second contact disposed on the second facet;

As an optional addition to the above, a first terminal may be provided that is attached to the first contact and a second terminal may be provided that is attached to the second contact.

According to yet another embodiment, an electrical component is provided, comprising:

a pored scaffolding having a plurality of pores and where at least one pore transverses the scaffolding from a first facet to a second facet;

at least one layer of anode material substantially spanning all surfaces of the scaffolding including in the pores of the scaffolding;

at least one layer of solid electrolyte material substantially spanning all surfaces of the scaffolding including in the pores of the scaffolding;

at least one layer of cathode material substantially spanning all surfaces of the scaffolding including in the pores of the scaffolding;

a first contact disposed on the first facet;

a second contact disposed on the second facet; and

insulation material that separate the anode from the cathode at the outer surface of the scaffolding, where all layers are deposited on the scaffolding and substantially covering all surfaces of the pores within the scaffolding.

As used herein, the term “substantially spanning all surfaces” generally means that the entire surface of a component (e.g., scaffolding or layers provided on scaffolding), have been covered by a layer including the inner surface of hidden features such as pores. This can usually be accomplished via ALD today, but other processes for forming layers of materials on surfaces of components can also be utilized to achieve the desired surface coating without departing from the scope of the present invention.

It will be appreciated by those skilled in the art that the concepts presented herein are applicable for use with a variety of other microelectronic and electronic components other than those listed above including low-capacitance capacitors, resistors, transducers, transformers, diodes, transistors, and conductors, to name a few. It is also to be understood that the present invention includes a variety of different versions or embodiments, and this Summary is not meant to be limiting or all-inclusive. That is, this Summary provides general descriptions of certain embodiments, but may also include more specific descriptions of certain other embodiments. For example, the concepts addressed herein are applicable to both the methods of manufacturing or constructing microelectronic and electronic components and sub-components, and to the components and sub-components manufactured by these methods as well. Furthermore, the use of the term component and/or sub-component is not intended to be limiting in any respect, and it is to be expressly understood that the methods of manufacturing and devices disclosed in varying embodiments herein may include complete, stand-alone devices, which are not dependent on other devices, such as with Printed Circuit Board (“PCB”) or Integrated Circuit (“IC”) components.

Accordingly, various embodiments of the present invention are illustrated in the attached figures and described in the detailed description of the invention as provided herein and as embodied by the claims. It should be understood, however, that this Summary does not contain all of the aspects and embodiments of the present invention and that the invention as disclosed herein is and will be understood by those of ordinary skill in the art to encompass obvious improvements and modifications thereto.

Additional advantages of the present invention will become readily apparent from the following discussion, particularly when taken together with the accompanying drawings.

### BRIEF DESCRIPTION OF THE DRAWINGS

FIG. 1 is a sectional view of a sintered capacitor manufactured according to one embodiment of the present invention;

FIG. 2 is a partial sectional view of the sintered capacitor shown in FIG. 1;

FIG. 3 is another partial sectional view of the sintered capacitor shown in FIG. 1;

FIG. 4 is yet another partial sectional view of the sintered capacitor shown in FIG. 1;

FIG. 5 is yet another partial sectional view of the sintered capacitor shown in FIG. 1;

FIG. 6 is yet another partial sectional view of the sintered capacitor shown in FIG. 1;

FIG. 7 is yet another partial sectional view of the sintered capacitor shown in FIG. 1;

FIG. 8 is yet another partial sectional view of the sintered capacitor shown in FIG. 1;

FIG. 9 is a sectional view of a nanopore capacitor according to at least one embodiment of the present invention;

FIG. 10 is a perspective view of scaffolding used for constructing a nanopore capacitor according to at least one embodiment of the present invention;

FIG. 11 is a partial sectional view of an electrochemical capacitor or a battery according to at least one embodiment of the present invention;

FIG. 12 is a partial sectional view of the capacitor shown in FIG. 9;

FIG. 13 is another partial sectional view of the capacitor shown in FIG. 9;

FIG. 14 is yet another partial sectional view of the capacitor shown in FIG. 9;

FIG. 15 is yet another partial sectional view of the capacitor shown in FIG. 9;

FIG. 16 is yet another partial sectional view of the capacitor shown in FIG. 9;

FIG. 17 is yet another partial sectional view of the capacitor shown in FIG. 9;

FIG. 18 is a sectional view of a nanopore capacitor built on a carrier according to at least one embodiment of the present invention;

FIG. 19 is a sectional view of an anodized nanopore capacitor with a nitride conductor and plug according to at least one embodiment of the present invention; and

FIG. 20 is a sectional view of a sintered capacitor with a nitride conductor and plug according to at least one embodiment of the present invention.

The drawings are not necessarily to scale and may be exaggerated in some instances to emphasize certain portions of the present invention.

### DETAILED DESCRIPTION

As discussed above, ALD is a manufacturing technique that allows one or more atomic or molecular layers of materials to be deposed on a surface, and has several benefits over other methods of manufacturing, including but not limited to providing consistent and reliable uniform coating thickness at exposed and hidden surfaces that are not achievable with previous technologies. A typical ALD process may be summarized as comprising multiple cycles, with each cycle comprising two precursor stages and two purge stages. Descriptions of ALD process are listed in the background section above.

By way of example but not limitation, an ALD process for deposition of Al₂O₃ is described herein. First, a reaction chamber in which the ALD is performed is evacuated. In the first precursor stage, the selected first precursor is introduced into the reaction chamber for the purpose of reacting with a surface. For example, Trimethylaluminium (trimethylaluminum) (TMA) gas may be used as the first precursor for reacting with all the surfaces in a reaction chamber. This includes the surfaces of the chamber itself and any part or parts placed in the chamber. The precursor stage continues until all the surface is passivated. Aluminum atoms are deposited attached to the surface and methyl groups are attached to the Al. Longer time is required if some surfaces are difficult to reach, such as the inner surface of holes, pores, cracks and the like. Following the reaction of the first precursor with the surface, the first purge stage is applied by evacuating the chamber to remove any excess precursor that did not react or undesired byproduct from the chamber. An inert gas may be introduced to the chamber for better purging of the precursor by basically “flushing” it.

In the second precursor stage, the selected second precursor is introduced into the reaction chamber. Continuing the example above, water vapor may be introduced to the chamber in order to induce a reaction between the water vapor and the dangling methyl groups that exist on the surface of the material. This reaction forms Aluminum-Oxygen chemical bonds, and further forms a new surface with exposed hydroxyl groups for the subsequent TMA precursor stage. After the second precursor element has been introduced and the surface has again passivated, the second purge stage is applied, similar to the first purge stage, and the excess precursor is expelled from the reaction chamber. The completion of two precursor stages and two purge stages is referred to as one cycle. The end result of an ALD cycle with the precursors as described above results in a single molecular layer of Al₂O₃ deposited on all surfaces open to the reaction chamber volume.

An ALD process may comprise multiple cycles, some times on the scale of thousands, in order to form the desired thickness. As each layer is conformally and uniformly deposed on to the material surface and each preceding layer, the desired thickness can be accurately and consistently controlled by the number of cycles. The ALD process can be monitored and controlled by a number of known control logic hierarchies, such as PC-based, PLC (programmable logic controller) based, or by other control systems.

ALD process is known to achieve very deep penetration into pores. However, for extremely deep penetration, each stage in a cycle can be prolonged to allow for the precursors or the purge gas time to penetrate the deepness of the pores. The vacuum pump that is connected to the chamber can be valved (shut away) from the chamber for the prolonged time of each stage of the cycle.

In current ALD technology, high quality processes for deposition can be achieved. By way of example but not limitation, the deposited materials can be Al₂O₃, ZrO₂, HfO₂, SiO₂, SrTiO₃, BaTiO₃, Ta₂O₅, TiO₂, HfSiO₄, La₂O₃, Y₂O₃, TiN, TaN, WN, Cu, W, TiSi₂, PtSi, CoSi₂, NiSi, WSi₂, Si₃N₄ etc. Currently, many tens if not hundreds of materials are known to be deposited by ALD. Materials known can be deposited by ALD includes dielectrics, conductors, anodes, cathodes, solid electrolytes etc. Each molecular layer is deposited in one cycle of the process, which takes approximately 0.5 to 5 seconds depending on the specifics of the ALD tool.

By way of example but not limitation, we will discuss a dielectric layer made of Al₂O₃. One molecular layer of Al₂O₃ has a thickness of ˜0.085 nm (0.85 Å). Other types of dielectric materials that may be used for the dielectric layer include, but are not limited to, Nb₂O₅, ZrO₂, HfO₂, SiO₂, SrTiO₃, BaTiO₃, Ta₂O₅, TiO₂, HfSiO₄, La₂O₃, Y₂O₃, Si₃N₄ and other non-conductive elements or materials. Although certain examples of dielectric layers will be described herein as including Al₂O₃, one skilled in the art will appreciate that the invention is not so limited to this type of dielectric and any other known type of dielectric material can be used in substitution of Al₂O₃ or as a supplement to Al₂O₃.

Assuming, for example, that the dielectric layer of Al₂O₃ needs to have a thickness of 10 nm. To reach this thickness, 120 layers need to be deposited. Using commonly available process tools, the ALD process will take approximately 60 to 600 seconds.

The ALD deposited Al₂O₃ has relative permittivity εᵣ of approximately 8. Calculation of the capacity of 1 cm² of a parallel plate capacitor made of a 10 nm thick layer of Al₂O₃ between two metallic electrodes is as follows:

C=εₒ*εᵣ*A/d εₒ=1/(36*π*10⁹)

Where εᵣ is the relative permittivity of the dielectric material, A is the area in m² and d is the insulation thickness in meters. C will be in Farads.

C=(1/(36*π*10⁹))*8*1*10⁻⁴/10*10⁻⁹=7*10⁻⁷=0.7 μF

Therefore a capacity of 0.7 μF/cm² can be achieved.

The dielectric breakdown voltage of Al₂O₃ is 8-10 MV/cm. Taking 8*10⁸ V/m:

V=10*10⁻⁹*8*10⁸=8 V

Using a voltage level of half of the breakdown, a useful operational voltage of 4V is therefore reasonable.

As an example of applications requiring higher voltage, a capacitor specified for 100 Volt with 0.028 μF/cm² could be deposited with 3000 layers of Al₂O₃. As one of ordinary skill in the art will appreciate, the material and the number of layers can be varied to achieve a wide range of capacitance and voltages for such a capacitor.

There is substantial research into materials suitable for construction of the components of batteries. There are several candidate materials for anode layer construction, by way of example but not limitation: Li₄Ti₅O₁₂, Ge(Li_{4.4}Ge), Si(Li_{4.4}Ge), Lithium-Titanate or Lithium Vanadium Oxide. The cathode layer can be constructed, by way of example but not limitation, from: LiFePO₄, LiCoO₂, LiMn₂O₄, LiNiO₂, LiMPO₄, where M stands for a metal such as Fe, Co, Mn, Ti, etc., LiFe_{0.95}V_{0.05}PO₄ or A₂FePO₄F where A=Na, Li. The solid electrolyte layer can be constructed, by way of example but not limitation, from: Lithium Phosphorous Oxynitride (Lipon), Lithium Lanthanum Titanate (LLT), Beta-alumina complexed with a mobile ions such as Na⁺, K⁺, Li⁺, Ag⁺, H⁺, Pb²⁺, Sr²⁺ or Ba²⁺, non-stoichiometric Sodium Aluminate, Yttria-stabilized zirconia (YSZ) or (Li,La)ₓTi_{y}O_{z}, to name a few.

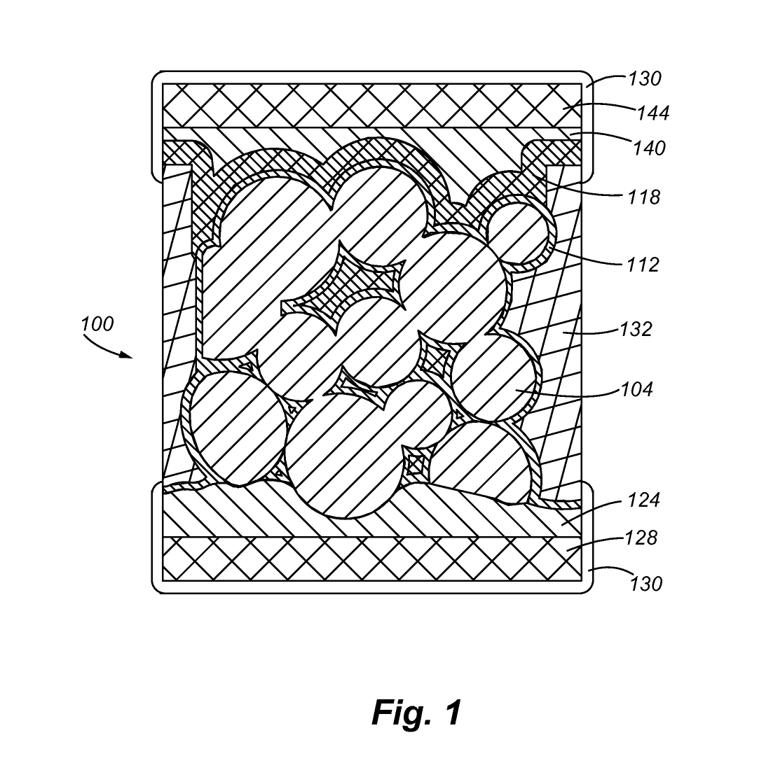

Referring now in detail to the drawings (FIGS. 1-20), various embodiments of the present invention are described.

According to an embodiments of this invention, sintered capacitors and a method of manufacturing sintered capacitors by ALD is disclosed. A sintered capacitor manufactured by ALD according to one embodiment is shown in a cross-sectional view in FIG. 1. It is important to note that the drawing of FIG. 1 is not to scale, as the whole structure is on a scale of millimeters while the spherical sintered particles are on a scale of micrometers or nanometers. The sintered capacitor 100 is comprised of sintered material 104. In a preferred embodiment, the sintered material 104 also acts as one of the electrodes of the sintered capacitor 100, and is preferably made of conductive metal. The sintered material have less then 100% fill, and includes material particles fuzed together by the sintering process and pores, where at least one pore transverses the scaffolding from a first facet to a second facet. Particle diameter between 0.1 μm and 10 μm is common in sintering metals, however for calculation purposes, by way of example but not limitation, it is assumed to be diameter of 1 μm. The whole surface of the sintered material 104 including hidden surfaces within the pores of the sintered material 104 is coated by dielectric material 112, which may have been deposited by ALD, according to methods described above. The complement vacant space left by the sintered material 104 and dielectric material 112 is filled, fully or partially, with an electrode material 118, that is made of conductive material. The electrode material 118 can be formed by an ALD process, or according to one alternative embodiment by other processes like wetting with molten metal, or a combination of the two processes. In a preferred embodiment, the sintered material 104 and the electrode material 118 are connected to terminals 128, 144 by filler 124, 140. In an alternate embodiment, the sintered material 104 and electrode material 118 are connected to terminals 128, 144 by solder 124, 140. Insulation 132 is preferably placed to minimize the possibility of shorts at the outer surfaces. The insulation 132 is preferably made of glass or plastic material.

In another embodiment of the present invention the dielectric layer 112 of the previous embodiment is replaced with layers of anode, solid electrolyte and cathode, made of materials described above, to create a battery or electrochemical capacitor. In an alternative embodiment the electrode material 118 is omitted, if the anode or cathode, whichever is away from the sintered material 104, can carry the electrical current.

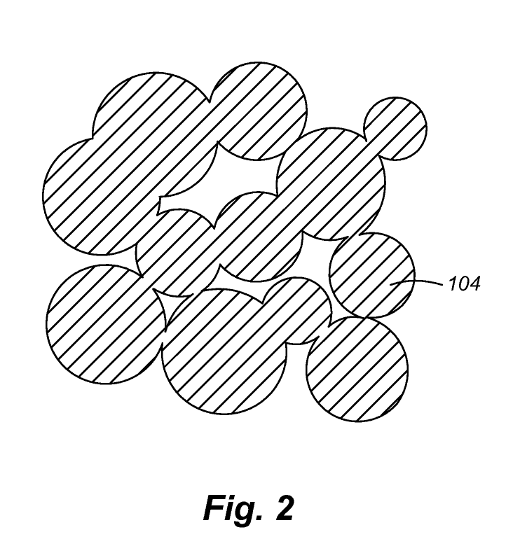

The detailed construction of the sintered capacitors will be better understood by the description of an embodiment of this invention, the method of manufacturing of a sintered capacitor. The construction process is described in relation to FIGS. 2-8. Referring now to FIG. 2, the sintered material 104 is shown in cross-sectional view as a sintered powder. The construction of the sintered capacitor 100 starts with creating the sintered material 104 to form an electrode by sintering of metal powder. It is preferred that one or more conductive metals such as Copper, Brass, Silver, Nickel, stainless steel, etc. are used. In one alternative embodiment, metal compositions such as Brass and/or metal particles coated with the same or another metal are used. In another alternative embodiment, non-metals, such as ceramics can be used if coated with metals either before or after sintering. During the known art of sintering, the metal powder is pressed and heated to a temperature below the melting point of the material, causing a localized merger of the particles. In FIG. 2, spherical shaped particles are shown, but other shapes are possible. The particles can be solid as shown in FIG. 2, or can be porous, depending on the material and the technique employed. The particles can have very uniform size or varieties of sizes. While the sintered body may have any shape or size, cube, right prism or cylinder shaped bodies from 1 mm in size to 10 mm in size will be more common in production. A fill ratio of 50% will be used herein as an example but not limitation, but other fill ratios can be used according to the known sintering processes. The volume of the sintered material is porous, where at least one pore transverses the scaffolding from a first facet to a second facet. By way of example but not limitation, if 1 micron particles are used, a cube of 2*2*2 mm³ dimension will have approximately 4*10⁹ particles at a fill factor of 50%, with total surface area of about 24,000 mm². These are very rough estimates since the actual numbers depends on the particle shape, size variations etc. For other situations the numbers may differ according to the material structure. The sintering process results in forming an electrode comprised of the sintered material 104.

According to yet another alternative embodiment, any porous material that was made by a variety of technologies can be used for the first electrode. Some porous materials have very large surface area that will be useful in creating a capacitor with large capacity. If not conducting, the material can be coated with at least one conducting layer.

According to yet another alternative embodiment, the sintered material is mostly un-oxidized, that is, there is no dielectric layer coating the sintered material, and if there is, it is very thin, thinner then the dielectric layer that is deposited in the next step.

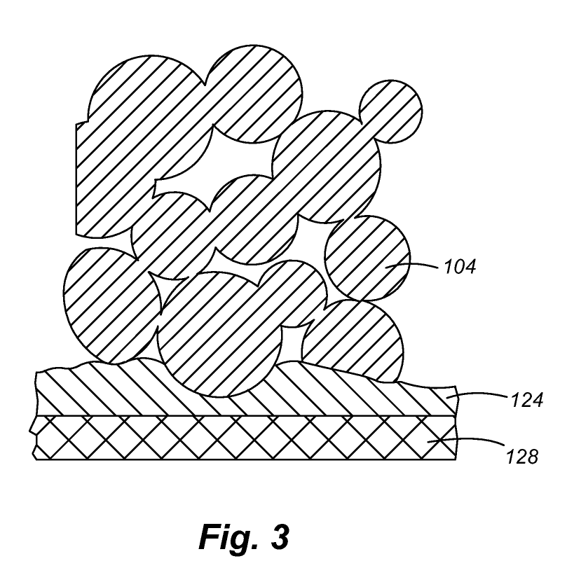

Referring now to FIG. 3, the bottom terminal 128 is preferably formed of convenient or common conductive metal, and is brazed to the sintered material 104 with filler 124. The surface of the sintered material 104 can be cleaned by etching or other technologies to remove any oxide layers to allow good wetting of the solder or filler material and as preparation for the following deposition steps. The brazing process could be made in the same chamber as used for the next step of manufacturing, by properly elevating the temperature to above the melting point of the filler.

In mass production, the bottom terminal 128 can be formed from a piece of sheet metal onto which thousands of cubes, right prisms or cylinders of sintered material 104 are brazed. The cross-sectional view of only one cube or cylinder is shown in FIG. 3 for clarity. By way of example but not limitation, common dimensions include a bottom terminal of approximately 0.5 mm thickness and 400*400 mm² width and length, on to which 10,000 cubes of 2*2*2 mm³ are brazed at a pitch of approximately 4 mm. Apart from brazing with filler 124, other forms of connection between the sintered material 104 and the bottom terminal 128 are possible, such as soldering, another step of sintering, or sintering the sintered material 104 while directly in contact with bottom terminal 128.

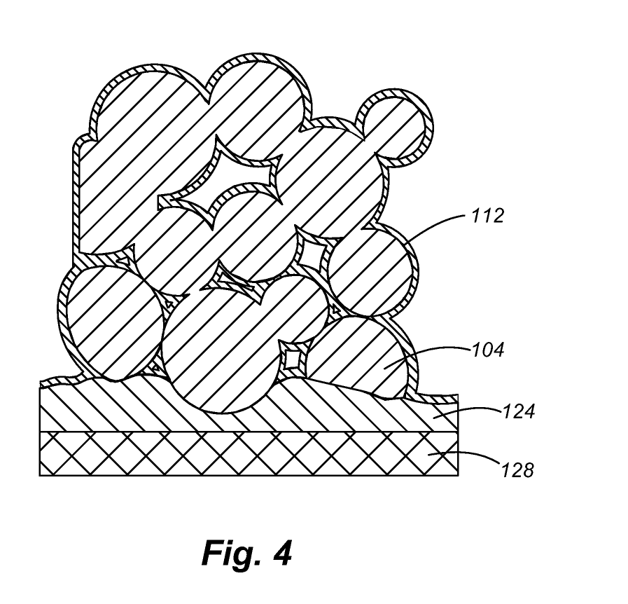

Referring now in detail to FIG. 4, a dielectric material layer 112 formed on the sintered material 104 is shown in cross-sectional view. In this step, ALD can be used to form the dielectric material layer 112 surrounding the electrode formed from the sintered material 104. ALD is specifically useful in this step, as it enables deposition of very well conformed layers of material into very deep cavities. The process, as explained above, is self-terminating to create one molecular layer in each cycle of the process. According to a preferred embodiment, the dielectric material layer 112 should have high dielectric constant and high dielectric strength. A known material in such ALD applications is Al₂O₃, used as an example above and below. In alternative embodiment, other dielectrics such as, by way of example but not limitation, Nb₂O₅, ZrO₂, HfO₂, SiO₂, SrTiO₃, BaTiO₃ or Ta₂O₅, TiO₂, HfO₂, HfSiO₄, La₂O₃, Y₂O₃, or Si₃N₄ can be used.

Using Al₂O₃ as an example, this material has a dielectric constant of approximately 8 and breakdown voltage of between 8-10 MV/cm. Assuming, by way of example but not limitation, that the objective is to manufacture a capacitor with 10 V operational voltage, and it is desired to have approximately 4 MV/cm or 4*10⁸ V/m as the working voltage. For a 10 Volt operational capacitor, the dielectric thickness is calculated as follows:

T=10/4*10⁸=2.5*10⁻⁸ m or 25 nm

Each molecular layer of Al₂O₃ is ˜0.085 nm in thickness. Therefore, approximately 300 layers are needed for dielectric layer 112. For different operational voltage the thickness changes nearly linearly.

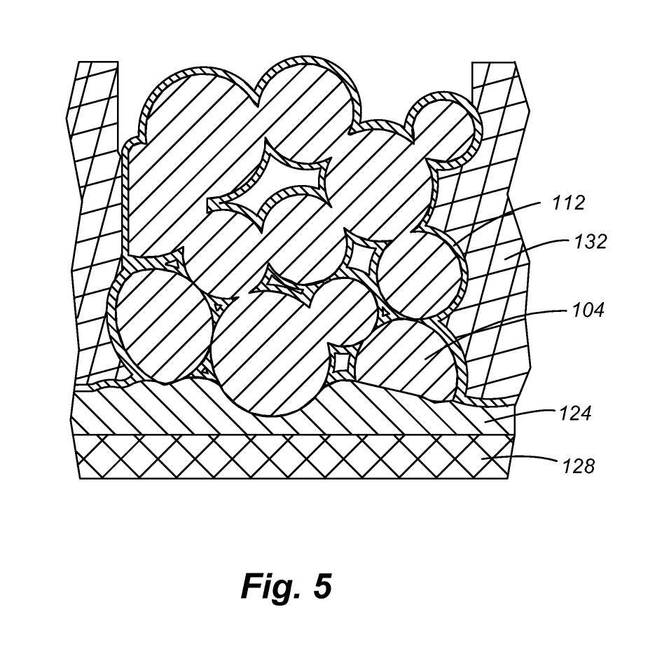

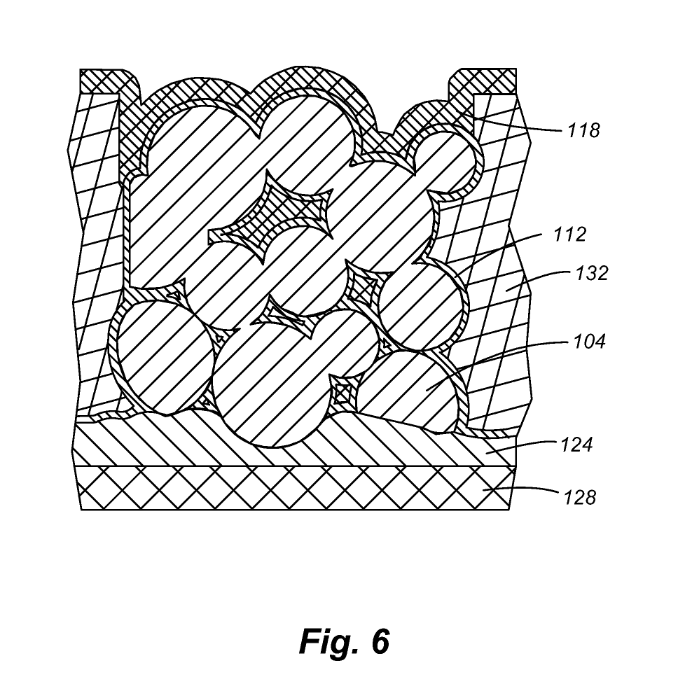

Referring now to FIG. 5, the next step is of adding insulation 132 on the sides of the dielectric material layer 112 coated sintered material 104. The reason for the insulation 132 is that it is undesired to create a periphery of the component where the two electrodes (sintered material 104 and electrode material 118) are separated by only a few nanometers (electrode material 118 is explained in detail later in relation to FIG. 6). According to a preferred embodiment, the insulation 132 is comprised of a thermo-setting or thermoplastic plastic with a high melting temperature. Alternatively, glass can be used to make the insulation 132, consisting of various kinds of glass materials. The coefficient of thermal expansion of the glass insulation 132 should be matched to the combined coefficient of the sintered material 104 and electrode material 118 to enable extreme working temperatures without damage to the glass. The insulation 132 may be structured as powder, a paste, or pre-formed material to fill in among the cubes, right prisms or cylinders of individual capacitors units and then set or re-flowed. The insulation 132 must be viscous enough not to wick into the bulk of volume between the sintered particles.

In another embodiment of this invention, the insulation 132 is placed before the dielectric 112 is formed. This variant will not change the performance of the capacitor 100 or similarly constructed electrical component.

Referring now to FIG. 6, a cross-sectional view of the sintered capacitor assembly is shown including the second electrode 118. In this step, ALD deposition of the electrode material 118 occurs. Metallic ALD may need substantial number of layers (up to several thousands) to fill in all spaces formed between the sintered material 104 particles. While ALD of metal or conductive material is preferred, other technologies can be used to complete this step. Molten metal under vacuum conditions can be used to create the electrode material 118 in a process very similar to soldering. A combination of first coating, by ALD, a metal that adheres well to the material of dielectric layer 112 and then melting-in another metal can also be used. In such a case, the ALD deposited layer will help the molten metal to wet the surface and wick in.

In an alternative embodiment, certain spaces may be left unfilled and blocked off in subsequent steps. The electrode material 118 is preferably deposited at a temperature that does not melt the insulation 132. According to one alternative embodiment, the electrode material 118 can be used as the top contact or another layer of material may be used as top contact as will be shown below.

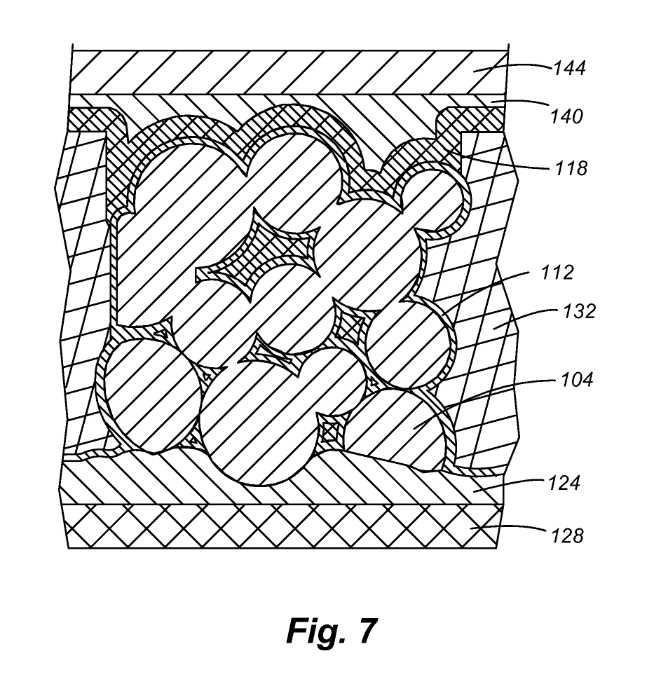

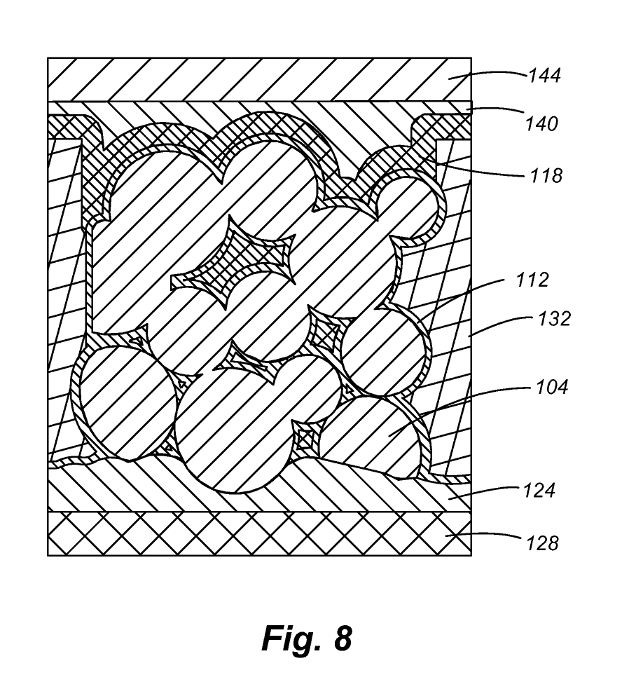

Reference to FIG. 7 is now made. The next step includes placing the top terminal 144 into the desired position. As seen in FIG. 7, the top terminal 144 is preferably brazed to the electrode material 118 with filler 140. The top terminal 144 will preferably have the same dimensions as the bottom terminal 128, and will be brazed to all the capacitors 100 in a single step. Brazing 140 can be performed under vacuum to keep any unfilled volume in the capacitor 100 evacuated and to hermetically seal all such unfilled volumes. Alternatively, brazing can be made under controlled environment to control what is left in the unfilled volumes. After this step, the individual sintered capacitors 100 will be formed by sawing the structure in the middle of the insulation in two directions, resulting in the capacitor shown in FIG. 8.

A solder barrier 130 can be applied to the top and bottom terminals 144, 128, as shown in FIG. 1, and this solder barrier 130 can be coated with solder material to prepare for assembly. In an alternative embodiment, laser marking can be applied. The manufacturing process described in various embodiments above results in the final component as shown in FIG. 1. The whole unit can be placed in a tape package for automatic assembly.

The capacity of a parallel-plate capacitor is calculated as follows:

C=εₒ*εᵣ*A/d where: εₒ=1/(36*π*10⁹)

Where εᵣ is the relative permittivity of the dielectric material, A is the area in m² and d is the insulation thickness in meters. C will be in Farads.

For the example capacitor described above:

A=24,000 mm² or 24*10 ³ m²

D=25 nm or 25*10⁻⁹ m

εᵣ=8 for ALD deposited Al₂O₃

C=εₒ*8*24*10⁻³/25*10⁻⁹=68 μF

The completed sintered capacitor 100 of the example will have dimension of about 3*3*3=27 mm³. The specific capacitance will be:

68*10/27=25 VμF/mm³

Comparing to typical Tantalum electrolytic capacitors at 7 VμF/mm³ and typical Aluminum electrolytic capacitors at 0.7 VμF/mm³ suggests vast improvements over present technology capacitors and methods of manufacture. Due to the construction of the sintered capacitor, having a high quality dielectric material, compared with electrolytic capacitors where the dielectric is made of electrically created oxides that have many deficiencies, it is expected that sintered capacitors will fully displace the electrolytic capacitors in the marketplace. The higher specific capacity will only add to the displacing force. The specific capacitance of the above discussion is an example only, and different sized and shaped powder, different sintering process used for making the sintered material, as well as different dielectric material will vary the specific capacitance. For example, using Ta₂O₅ as dielectric will increase the specific capacitance substantially.

In an another embodiment of the present invention a battery is constructed. The dielectric layer of previous embodiments will be replaced with deposition of anode layer, solid electrolyte layer, and cathode layer, all deposited by ALD process, in this order or the reverse order. There are several candidate materials for anode layer construction, by way of example but not limitation: Li₄Ti₅O₁₂, Ge(Li_{4.4}Ge), Si(Li_{4.4}Ge), Lithium-Titanate or Lithium Vanadium Oxide. The cathode layer can be constructed, by way of example but not limitation, from: LiFePO₄, LiCoO₂, LiMn₂O₄, LiNiO₂, LiMPO₄, where M stands for a metal such as Fe, Co, Mn, Ti, etc., LiFe_{0.95}V_{0.05}PO₄ or A₂FePO₄F where A=Na, Li. The solid electrolyte layer can be constructed, by way of example but not limitation, from: Lithium Phosphorous Oxynitride (Lipon), Lithium Lanthanum Titanate (LLT), Beta-alumina complexed with a mobile ions such as Na⁺, K⁺, Li⁺, Ag⁺, H⁺, Pb²⁺, Sr²⁺ or Ba²⁺, non-stoichiometric Sodium Aluminate, Yttria-stabilized zirconia (YSZ) or (Li,La)ₓTi_{y}O_{z}, to name a few.

In this embodiment, the insulator is installed either before or after the step of depositing the solid electrolyte in order to separate the anode from the cathode macroscopically at the terminals.

In another embodiment of the present invention, a battery is constructed omitting the step of installing the electrode material 118, relying on either the cathode or the anode, whichever is not in contact with the sintered material 104, to carry electrical current to the second terminal.

The construction of the sintered material with ALD deposited anode, cathode and solid electrolyte will render the structure more durable then conventional batteries with CVD coated carbon structures. The capacity of ALD process to deposit defect free and pinhole free layer is important for the deposition of the solid electrolyte, in order to prevent internal short circuit between the anode and the cathode. In addition, due to the very short ion transport length, the battery internal resistance will be low and it will have fast charge and discharge times.

In another embodiment of the present invention, an electrochemical capacitor is constructed. Similar to the previous embodiment there are anode layer, solid electrolyte layer and cathode layer, all deposited by ALD process. There are several candidate materials for anode, cathode and solid electrolyte layer construction, by way of example and not limitation, similar to the materials listed above for batteries.

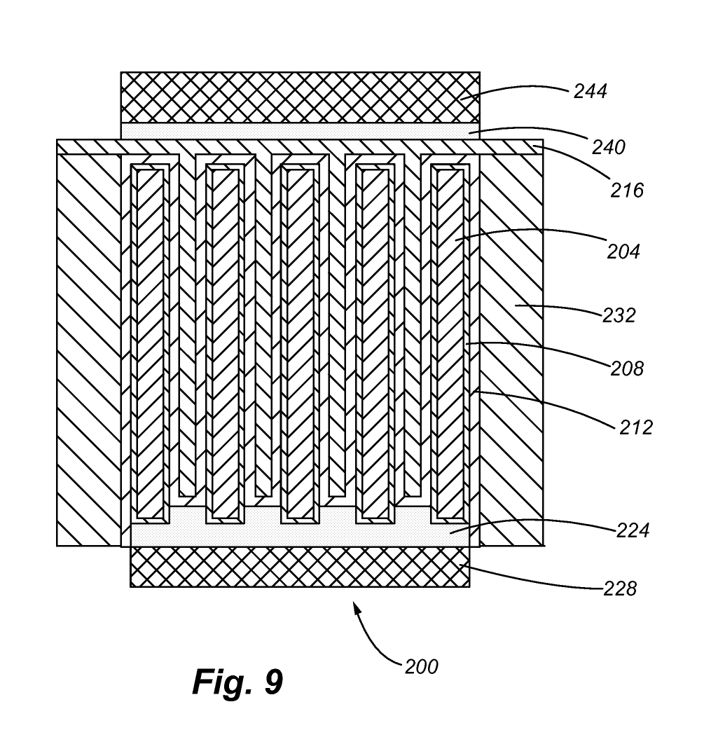

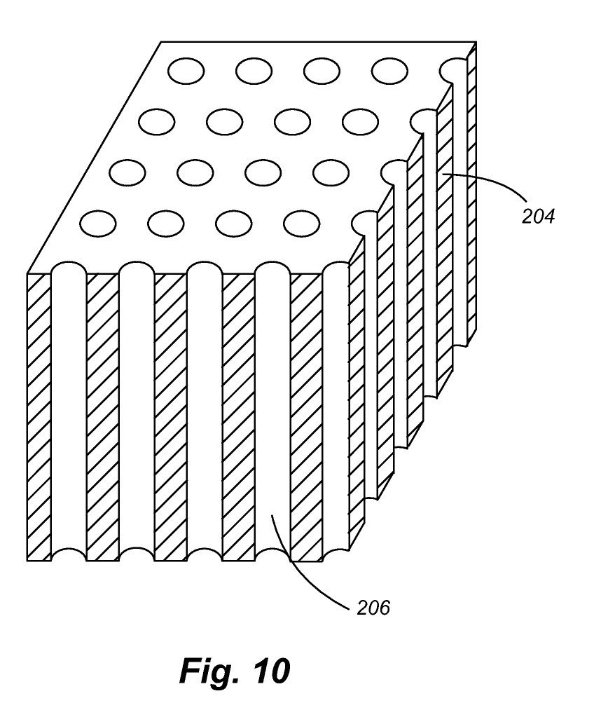

Referring now to FIGS. 9-17 an exemplary nanopore-type capacitor 200 will be described in accordance with embodiments of the present invention. In particular, and as can be seen in FIG. 10, the capacitor 200 includes scaffolding 204 made of nano-pored Al₂O₃ or a similar type of material. The scaffolding 204 comprises nanometer scale diameter pores 206 where at least one pore transverses the scaffolding from a first facet to a second facet.

Accordingly, although FIG. 9 only depicts four pores 206 in the cross-section of the scaffolding 204 and FIG. 10 only depicts a relatively small number of pores 206, one skilled in the art will appreciate that depiction of the scaffolding 204 and other components of the capacitor 200 to scale would not facilitate a ready understanding of the present invention. In particular, not-to-scale figures have been provided for clarity and to further the understanding of the present invention and one skilled in the art will appreciate that many thousands or millions of pores 206 may be present in a single cross-sectional view of the capacitor 200. The size of the whole assembly is on the order of few hundreds of micrometers to several millimeters on the side and the pores 206 are several tens to few hundreds of nanometers in diameter. Moreover, the pores 206 may comprise a length ranging from between a few of micrometers up to several millimeters.

By way of example but not limitation, calculation is made of the number of pores in a scaffolding 204 of 2×2×2 mm³ with average pore 206 diameter of 100 nm. The cross-section area of a pore 206 is:

a=π*D²/4=3.14*(100*10⁻⁹)²/4=7.85*10⁻¹⁵ m²

Assuming that the pore 206 total cross-section area covers half of the total available area of a facet of the scaffolding 204. The number of pores 206 equals approximately:

N=0.5*(2*10⁻³)²/7.85*10⁻¹⁵=254*10⁶

It is, therefore, appreciated that approximately 16,000 pores 206 will be seen in a cross-section of a scaffolding 204.

In one embodiment of this invention, as seen in FIGS. 9 and 10, the nanopore capacitor 200 is constructed of:

nanopore scaffolding 204 having multiple pores 206 where at least one pore transverses the scaffolding from a first facet to a second facet;

a conductor 208 conformal to the scaffolding 204 and substantially all exposed surfaces of the scaffolding 204 and substentially all internal surfaces of the pores, thereby acting as the first electrode of the capacitor;

dielectric 212 conformal to the conductor 208;

a plug 216 conformal to the dielectric 212 and acting as the second electrode of the capacitor;

a bottom terminal 228 attached to conductor 208 with filler or solder 224 and acting as a first contact area to connect the capacitor to other electronic components, wires, PCBs and the like;

a top terminal 244, attached to plug 216 with filler or solder 240 and acting as a second contact area to connect the capacitor to other electronic components, wires, PCBs and the like; and

insulation 232, disposed on the circumference of the capacitor 200 to physically separate the two terminals of the capacitor 200 and substantially all conducting material connected to them.

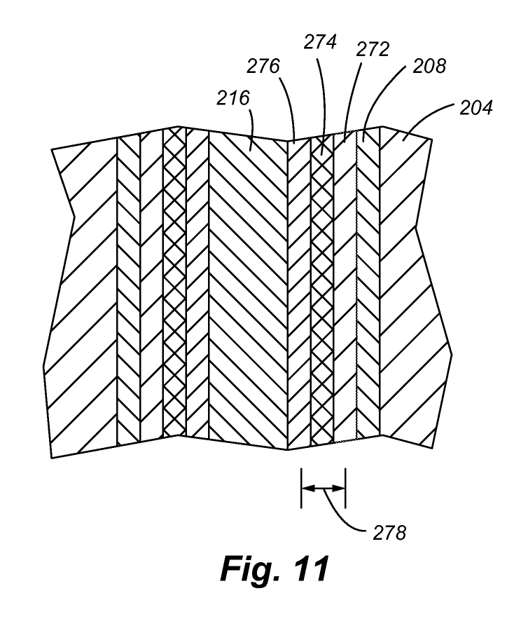

In another embodiment, electrochemical capacitors and batteries can be constructed by replacing the dielectric 212 with layers of cathode, solid electrolyte and anode. A part of a pore of this embodiment is shown in FIG. 11, greatly magnified and not to scale. The pore is shown inside scaffolding 204. In the pore there are concentric layers of conductor 208, anode 272, solid electrolyte 274, cathode 276 and plug 216. For a similar performance, the location of anode layer 272 and the cathode layer 276 may be reversed. The ion transport length 278 is the distance ions needs to travel during charge and discharged. By way of example and not limitation, the materials of the anode, cathode and solid electrolyte can be as discussed above, and ion transport length 278 is on the order of tens of nanometers, resulting in low resistance and fast charge and discharge.

Although FIG. 11 generally depicts a five layer construction within the pore of the scaffolding 204, one skilled in the art will appreciate that a three layer construction may also be utilized without departing from the scope of the present invention. In particular, a cathode, electrolyte, and anode layer may be provided in substantially all of a pore if the conductivity of the cathode and anode layers are sufficient to support the desired operation of a battery.

Another embodiment of the present invention is the method of manufacturing a nanopore capacitor 200. The explanation of the method will aid in understanding the structure of the nanopure capacitor 200. The method of constructing nanopore capacitor 200 will be explained referring to FIGS. 9, 10 and 12-17. Similar to FIGS. 1-11, FIGS. 12-17 are not necessarily drawn to scale.

In some embodiments, the scaffolding 204 is made from metallic Aluminum by driving an electrical current through the Aluminum while using an acidic electrolyte, resulting in scaffolding 204 made of Al₂O₃ (sapphire). The construction of the scaffolding 204 is described in further detail in U.S. Pat. Nos. 3,574,681; 3,850,762; 4,687,551; and 5,112,449, all of which are hereby incorporated by reference in their entirety. Furthermore, a commercial product manufactured by Whatman Ltd., and marketed under the registered trade name Anopore®, is provided as a particulate filter. See http://www.whatman.com/PRODAnoporeInorganicMembranes.aspx and http://www.2spi.com/catalog/spec_prep/filter2.shtml which are incorporated herein by reference in their entirety. To be useful as a particulate filter in a flow of gas or liquid, the pores need to extend from a facet where the flow enters to a facet where the flow exits the filter. The size of the pores 206 can be controlled by the process parameters: type of electrolyte, amount of current etc. Standard diameter pores are commercially available in the sizes of 20 nm, 100 nm, and 200 nm. One skilled in the art will appreciate that the sizes of the pores 206 used in the capacitors described herein may vary according to component design and customer preferences. One skilled in the art will also appreciate that similar scaffolding can be made by different technologies, such as directional etching of a crystal trough a mask and other technologies.

Uniquely and advantageously, a very tight distribution of pore 206 sizes within the scaffolding 204 can be achieved utilizing known processing techniques. The pores 206 are continuous and generally uniform in diameter from the top facet of the scaffolding 204 to the bottom facet of the scaffolding 204. There are generally no inter-connections, branching or crossings between pores 206, however, if there are any inter-connections, branching or crossing of pores it will not cause any difficulty for manufacturing or any difference in performance of a component according to any of the embodiments herein. Moreover, the material used to construct the scaffolding 204 is inert and capable of withstanding extreme environment conditions such as elevated temperatures, corrosive liquids, and so on.

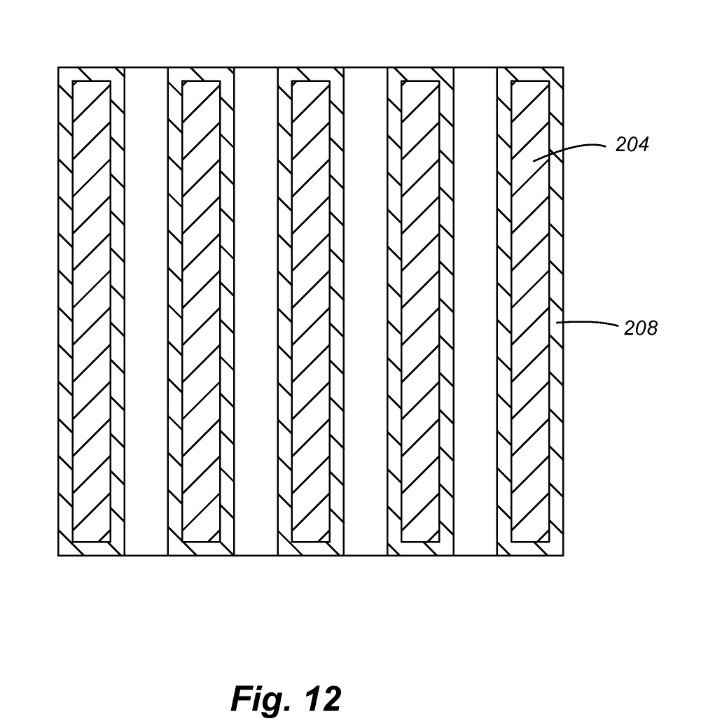

Referring now to FIG. 12, the scaffolding 204 of the nanopore capacitor 200 is covered by a first conductor 208 via an ALD process, which includes multiple cycles resulting in the deposition of multiple layers of the first conductor 208. In some embodiments, the first conductor 208 comprises a metal or semiconductor material. The first conductor 208 is provided to act as a first electrode of the capacitor 200 and may have a thickness ranging from a few nanometers up to tens of nanometers.

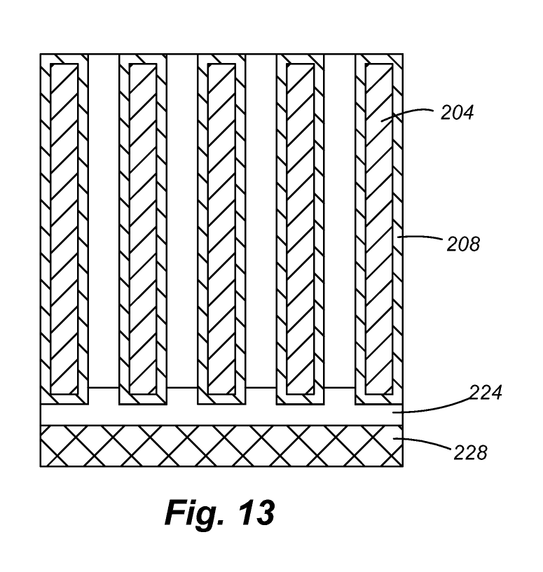

As seen in FIG. 13, once the first conductor 208 is satisfactorily deposited on the scaffolding 204, the scaffolding 204 with first conductor 208 may be brazed, soldered, or sintered with filler 224 to a base terminal 228. Base terminal 228 is made of metal and is used for making the electrical connection out of the capacitor to an electrical circuit external to the capacitor 200. Also, filler 224 may be provided to seal the pores 206 of the scaffolding 204 on the bottom side of the scaffolding 204 and also facilitate an electrical contact between the first conductor 208 and the base terminal 228. The base terminal 228 may have a thickness ranging, by way of example and not limitation, from a few hundred microns up to over a millimeter.

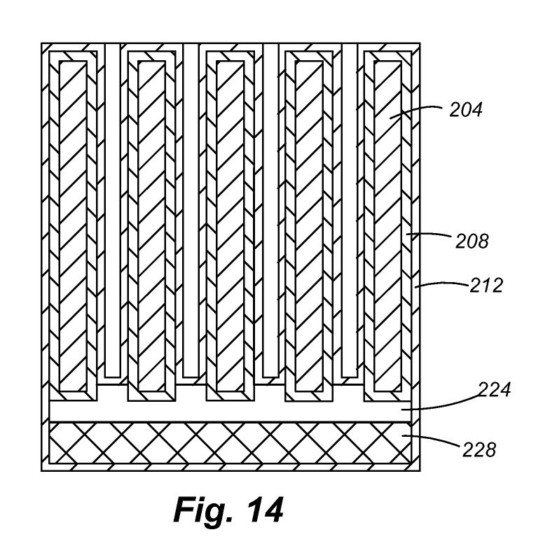

Referring now to FIG. 14, a layer of dielectric 212 is then deposited on the entire structure (scaffolding 204, first conductor 208, filler 224 and base terminal 228) using an ALD process. The thickness of the dielectric 212 is designed for a certain and predefined working voltage. ALD provides a mechanism which creates a complete layer of dielectric 212, with no defects, pinholes or any other points of first conductor 208 exposure, thereby reducing or eliminating the opportunities for a short circuit in the capacitor 200. In some embodiments, the dielectric 212 may have a thickness ranging by way of example and not limitation, from a few nanometers up to tens and even hundreds of nanometers depending of the required capacitance and operation voltage.

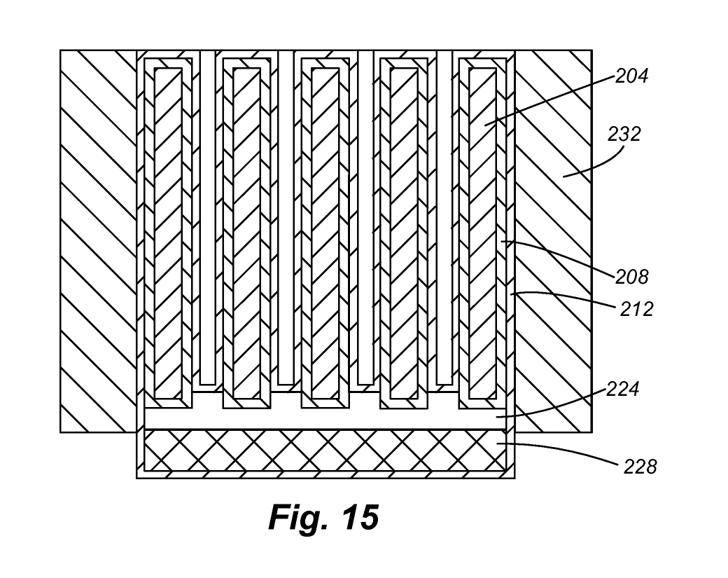

As seen in FIG. 15, an insulator 232 is then placed on the circumference surface of the scaffolding 204. In other words, the insulator 232 is placed on the surfaces of the scaffolding 204 whose plane would dissect an entire pore 206 (i.e., on the surfaces of the scaffolding 204 on which no pore openings 206 are exposed). In some embodiments, the insulator 232 comprises a thickness ranging by way of example and not limitation, from a few hundred microns up to over a millimeter.

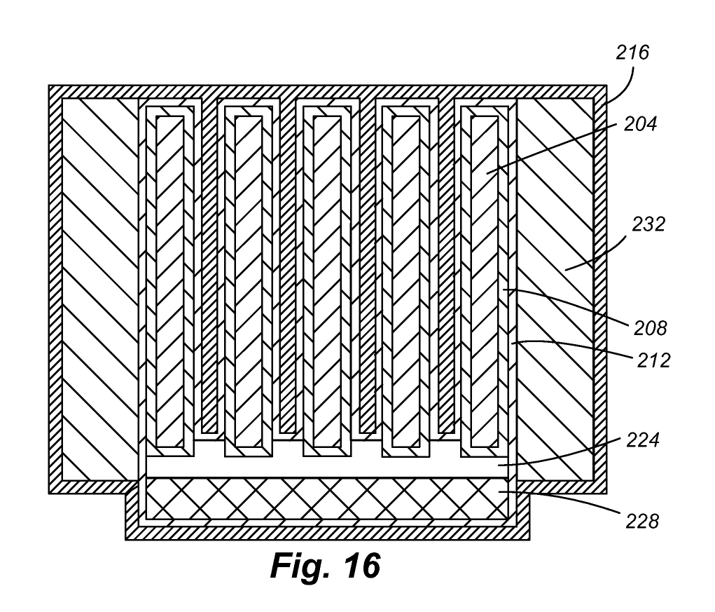

Referring now to FIG. 16, a plug 216 is deposited using ALD to substantially fill the remainder of the pores 206 not already filled by the first conductor 208 and dielectric 212. The plug 216 acts as the second electrode of the capacitor 200 and may include a metal or semiconductor material. In some embodiments, plug 216 comprises a thickness ranging from about ten nanometers up to a 100 nm. In some embodiments, plug 216 does not fill pores 216.

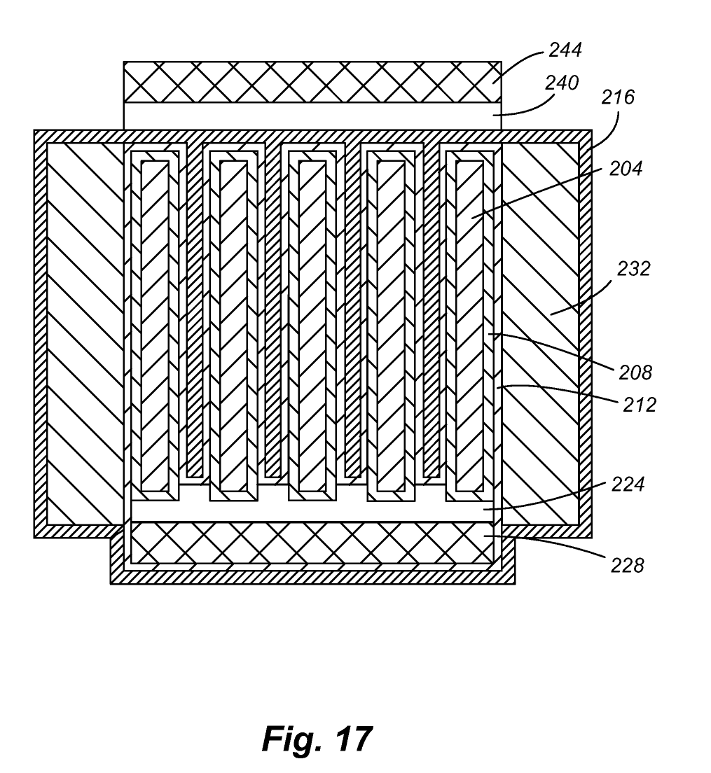

As seen in FIG. 17, a top terminal 244 is then soldered, brazed, or sintered to the top of the plug 216 with a filler 240. In some embodiments, the top terminal 244 comprises a thickness ranging from a few hundred microns up to over a millimeter. The excess layers of the plug 216 and dielectric 212 are then etched or ground away to arrive at the capacitor 200 depicted in FIG. 9.

The resulting capacitor 200 may comprise a specific capacity, by way of example and not limitation, of 400 VuF/mm³ as compared to 7 VuF/mm³ provided by conventional Tantalum electrolytic capacitors. Furthermore, the series resistance of the capacitor 200 is on the order of micro-ohms and the series inductance is very low, thereby resulting in an extremely high performance. Due to the construction of capacitor 200, it will have high reliability, expanded working temperatures and substantially longer life-expectancy than traditional electrolytic capacitors.

In another embodiment, similar to the discussions above, electrochemical capacitors and batteries are constructed by replacing the step of depositing dielectric 212 with several steps of depositing, by ALD, cathode 276, solid electrolyte 274 and anode 272, in that or the reversed order, as depict in FIG. 11. In this embodiment, the insulation 232 should be installed before or after deposing the solid electrolyte 274.

According to yet another embodiment, a method of manufacturing electrochemical capacitor or battery is provided as in the previous embodiment but with the step of depositing the first conductor 208 and the plug 216 omitted and the cathode and anode carry the electrical current to the terminals.

Referring now to FIGS. 9-17, a process for constructing a nanopore capacitor 200, electrochemical capacitor or battery will be explained in further detail. Similar to FIGS. 1-8, FIGS. 9-17 are not necessarily drawn to scale. After a scaffolding 204 has been provided, the manufacturing process continues with the creation of the first electrode of the capacitor 200, electrochemical capacitor or battery. In particular, the scaffolding 204 is coated with a conducting material, thereby resulting in the first conducting layer 208. By way of example but without limitation, the material used to construct the first conducting layer 208 can be a pure metal such as Silver, Copper, Gold, Indium, Aluminum, Tungsten, Nickel, Cobalt, Iron, Titanium, Ruthenium, Zinc, Tin, Tantalum, or combinations thereof. The first conducting layer 208 can alternatively, or in addition, be constructed of a semiconductor material such as Doped Silicon, Doped Germanium, or the like. Alternatively, or in addition, the first conducting layer 208 can comprise a metal nitride such as TiN, TaN, WN, metal Silicide such as TiSi₂, PtSi, CoSi₂, NiSi, WSi₂ and the like. Alternatively, or in addition, the first conducting layer 208 can comprise a combination or layered materials. Alternatively, or in addition, the first conducting layer 208 can comprise any electrically conducting material or any conducting composition or layers of conducting materials or compositions. Preferably, the first conductor 208 exhibit a relatively low resistance, thereby making metals or metal compounds a suitable choice. Different types of layers of different materials can also be used to construct the first conductor 208. In some embodiments, if a non-metal is used to construct at least some of the first layers deposited on the scaffolding 204, then some of the last layers deposited on the scaffolding as the first conductor 208 may comprise metal, thereby facilitating adequate adhesion in later steps and possibly diffusion blocking barrier.

As noted above, and as can be seen in FIG. 12, the first conductor 208 is preferably deposited using an ALD process. The ALD process causes atomic or molecular layers to be deposited in an extremely conformal way. Each cycle of the ALD process deposit one atomic or molecular layer and to deposit N layers there is a need to simply run N cycles of the process. Due to the high aspect ratio of the pores 206, other deposition technologies known today are not practical, since the center area of the pores 206 will be under-coated. The scaffolding 204 may be placed in the ALD process chamber on a surface treated not to accept coating, however, this is not a requirement. With a limited contact area between the scaffolding and the surface, most of the bottom of the scaffolding will get almost fully coated. Due to the possibly enormous aspect ratio of the pores 206, on the order of up to 100,000:1, a long dwell time will be required for the precursors in the reaction chamber as well as long purge times.

The first conductor 208 is configured to act as the first electrode of a capacitor 200 or a first current carrying element of an electrochemical capacitor or a battery that carry current from the battery electrode to the terminal. It should have a reasonable thickness, perhaps on the order of 1-30 nm, depending on the maximum series resistance allowed. As one non-limiting example, about 70 atomic layers of Copper can be deposited using ALD with a resulting thickness of about 10 nm. Note that the first conductor 208 can be omitted if the anode or cathode, whichever is deposited first, have sufficient electrical conductance for proper operating in the final component.

In some embodiments, a diffusion barrier layer may be deposited on the scaffolding 204 before the deposition of the first conductor 208, to prevent diffusion of metal into the scaffolding 204. Another barrier layer may be deposited after the deposition of the first conductor 208, to improve adhesion to the electrical contact that is made in the next step, and maybe to prevent diffusion to the dielectric.

The vacuum condition and elevated temperature used in connection with the ALD process may be maintained for a predetermined amount of time before starting the coating process, particularly in an attempt to remove any moisture trapped in the scaffolding 204 after its manufacture in an acid bath. In addition, active reagents may be introduced to the reaction chamber to chemically attach to impurities and be removed.

The next step depicted in FIG. 13, includes the step of attaching a base terminal 228 to the scaffolding 204. This base terminal 228 will act as the first electrical contact of the capacitor, electrochemical capacitor or battery 200 and will also facilitate a connection point for wires or similar electrical contacts . In some embodiments, the base terminal 228 will be directly soldered to a pad on a PCB via surface mounting technology, for example.

The attachment of the base terminal 228 will be done in such a way as to have good electrical contact to the first conductor 208 in and adjacent to the opening of a substantial majority of the pores 206. This is critical to achieve low series resistance. The thickness of the first conductor 208 can range between a few up to tens of nanometers, and the base terminal 228 should generally not be conformal to the flatness of the scaffolding 204 to such an extent. The base terminal 228 can be sintered by being heated to a temperature at which it becomes soft and conforms to the desired shape, perhaps with an applied force. It should be noted that the scaffolding 204 comprises an extremely hard material. In some embodiments, the attachment can be achieved by brazing, where a thin layer of filler 224 is disposed between the base terminal 228 and the first conductor 208. The filler layer 224 should be thin such that it will not wick too much into the pores 206. The filler 224 can be electroplated on or rolled with the base terminal 228 to an accurate thickness.

Sputtering, evaporation coating, CVD or similar technologies can be used to cover one facet of the scaffolding 204 with metallic layer of material to become part of the filler 224. Due to the limited penetration of the CVD, evaporation coating or sputtering process, very limited amounts of the filler 224 will end up in the pores 206. However, the pores 206 will be effectively closed on the bottom side where the filler b 224 has been deposited, thereby enabling brazing or soldering of the base terminal 228 to the scaffolding b 204 with no or limited filling the pores 206 of the scaffolding 204.

If the previous step resulted in an unsatisfactory thickness of the first conductor 208 on the bottom of the scaffolding 204, perhaps due to a large contact area with the surface on which it rests in the process chamber, the top facet of the scaffolding 204 and first conductor 208 may be attached to the base terminal 228 (that is, the scaffolding 204 is inverted upside-down between FIGS. 12 and 13).

In some embodiments, ALD deposition of the first conductor 208 is utilized, then in the same chamber, CVD, evaporating, sputtering or the like of metal on top of the scaffolding 204 that almost or fully closes the top end of the pores 206 is employed. Thereafter, the scaffolding 204 may be inverted to rest on the base terminal 228 for soldering or brazing.

In some embodiments, the ALD process of depositing the first conductor 208 is performed while the scaffolding 204 is resting on the base terminal 228. Following the ALD process (which also possibly resulted in a coating of the base terminal 228), the temperature is raised to achieve the brazing step. In this scenario, a thin layer of conductor is deposited on top of the filler 224 which is sintered to the first conductor 208 on the scaffolding 204, and the filler 224 is allowed to soften for full area contact.

In some embodiments, it is a known art to manufacture nanopored Al₂O₃ in such a way that one side of all the pores 206 ends in a conducting material at one facet of the scaffolding. See e.g., U.S. Pat. No. 6,838,297 to Iwasaki et al, which is hereby included by reference in its entirety. In such an embodiment, the separate and distinct step of attaching the base terminal 228 to the scaffolding 204 is avoided. The step of depositing the first conductor 208 is made with the base terminal 228 already attached.

Note that one large metal plate can be used as the base terminal 228 and be used to attach hundreds or thousands of scaffolding+conductor 204+208 units, and will be separated to individual units (i.e., individual capacitor 200, electrochemical capacitor or battery units) later in the production process.

As can be seen in FIG. 14, the next step of the manufacturing process comprises of depositing a dielectric 212 on the structure. The dielectric 212 is preferably deposited using an ALD process and is provided to act as the dielectric of the capacitor 200. Dielectric 212 must be defect free and pinhole free to avoid internal shorts which can render the capacitor useless. The ALD process is uniquely adequate for such a need.

In some embodiments, the dielectric 212 may comprise, for example, a metal oxide such as Nb₂O₅, Ta₂O₅, Al₂O₃, ZrO₂, HfO₂, SiO₂, TiO₂, La₂O₃, Y₂O₃, HfSiO₄, SrTiO₃, BaTiO₃ or nitrides such as Si₃N₄. Many other dielectric materials can be used without departing from the scope of the present invention. It may be beneficiary to use a combination of materials such as Al₂O₃—HfO₂ laminates or a mixture such as (Al₂O₃)ₓ (HfO₂)₁₋ₓ, HfAlO(N), HfSiO(N), HfₓSi₁₋ₓO₂ etc. All such depositions and many more are known art in the ALD field and there is a research for many more dielectric materials for ALD processes.

By way of example but not limitation, Al₂O₃ is a very common material to be deposited by ALD, and to create 10 nm thick layer, about 118 molecular layers of Al₂O₃ are needed. Al₂O₃ is relatively easy to deposit using highly volatile Trimethylaluminium (“TMA”) as one of the precursors. The high volatility of TMA will help deep penetration of the dielectric 212 into the pores 206 in a process chamber carrying thousands or millions of assemblies.

The relative permittivity of the dielectric may be lower if the dielectric 212 is not closely packed, which is a possibility where an amorphous structure is made. For example, the relative permittivity of crystalline Al₂O₃ is between 9 and 11, depending on the optical axis direction of the crystal, but for ALD deposition it is between 7 and 8.

Before and after the dielectric layer 212 is deposited, a thin barrier layer may be deposited to prevent diffusion of metal into the dielectric. A common barrier for Copper is TaN.

Note that the dielectric layer 212 is depicted as coating the bottom of the base terminal 228 in FIG. 14. This may be prevented by providing a special blocking material on the bottom of the base terminal 228 during the ALD process in which the dielectric 212 is deposited. Following the ALD process, the blocking material may be removed, thereby exposing terminal 228. Alternatively, the dielectric 212 is allowed to be deposited on the bottom of base terminal 228 and is removed later by etching or grinding.

The next step of the manufacturing process is depicted in FIG. 15, in which an insulator 232 is placed about the structure. The insulator 232 may be made of glass or plastic. The insulator 232 is useful for separating the two electrodes of the capacitor 200 and enabling the handling of the unit by soldering onto a PCB board or the like. This would be difficult in the absence of having an insulator 232 since the two electrodes are separated by a few or tens of nanometers.

The insulator 232 should have good adhesion to the dielectric 212. Alternatively, a thin layer of a material with good adhesion to insulator 232 is deposited after dielectric 212 is deposed. In some embodiments, the insulator 232 is attached to the structure on four sides of the scaffolding 204 if it is a cube or right prism, as depicted in FIG. 10, or to the circumference if the scaffolding is a cylinder (not shown), and not on the top facet and the bottom facet of the scaffolding 204 where the pores 206 ends. Glass could be melted and re-flowed around the unit. Plastic such as epoxy resin can be applied. The insulator 232 should be low out-gassing, so it does not damage the next ALD step. If glass is used, the thermal coefficient of expansion can be selected to match the combined coefficient of the other parts of the structure.

The order of the steps of depositing the dielectric 212 and the placing of insulator 232 can be reversed without much difference in the final product.

Following the addition of the insulator 232, the manufacturing process continues as can be seen in FIG. 16. In particular, the second electrode of the capacitor 200 or the second electrical contact of an electrochemical capacitor or a battery is constructed as a plug 216. The plug 216 is constructed by utilizing an ALD process where conductive material, similar or identical to the first conductor 208, is added to the structure. In some embodiments, the material used for the plug 216 is different from the material used for the first conductor 208 (e.g., one is a a metal while the other is a different metal, or one is a metallic material whereas the other is a semiconductor material or a nitride of a metal, etc.)

In some embodiments, the plug 216 substantially fills the voids in the pores 206 not already filled by other materials. The number of ALD molecular or atomic layers added to construct the plug 216 can be such that even the largest pore 206 is filled.

In some embodiments, the ALD layer of the plug 216 will be designed not to fill the entirety of every pore 206, in which case a subsequent CVD, evaporation coating, sputtering or similar deposition process can be used to close and hermetically seal the open pores 206. In such a case, some trapped voids may exist within one or more of the pores 206, but if such voids are filled with low pressure gas from the CVD, evaporation coating or sputtering process and hermetically sealed from the environment, then the operation of the capacitor, electrochemical capacitor or a battery should not be compromised.

In some embodiments, some pores 206 are left exposed and treated in subsequent manufacturing steps.

In some embodiments, a thin barrier layer may be deposited after the plug 216 was deposited, to prepare the surface to the next step.

Similar to the case with the dielectric 212, the plug 216 may be provided in such a manner as to coat the structure in its entirety.

A top terminal 244 is then provided in the next manufacturing step depicted in FIG. 17. As can be seen in FIG. 17, the top terminal 244 is depicted as being brazed to the plug 216 with a metallic filler 240. However, soldering can be used. In both options, soldering or brazing can be performed in vacuum conditions or in a controlled environment, so that any void or exposure of the pores 206 is either filled or remains hermetically sealed and containing either vacuum or controlled material. Alternatively, a top terminal 244 can be manufactured directly on the plug 216 by electroless plating, electroplating or any other process that is capable of producing thick layer of metal of desired composition. If the construction is made of many units sharing large bottom terminal 228 and top terminal 244, a step of sawing the structure in two orthogonal directions along the center of the insulation 232 is used to separate the individual capacitors, batteries or electrochemical capacitors.

The final step of manufacturing is to remove the unwanted plug 216 and dielectric 212 by etching or grinding. Some thickness of the insulation 232 and terminals 228, 244 may be removed as well. After the unwanted plug 216 and dielectric 212 have been removed, the finished capacitor 200 depicted in FIG. 9 is achieved. In some embodiments a solder barrier similar to solder barrier 130 in FIG. 1 may be installed if needed.

For performance calculation it is assumed, by way of example but not limitation, that a capacitor was made from a scaffolding 204 of 1×1×1×1 mm³ nano-pored Al₂O₃, with average pore 206 diameter of 70 nm, the conductor layer 208 is 10 nm thick, the dielectric layer 212 is 10 nm thick, and the plug 216 diameter is nominally 30 nm. The cross-section area of a pore 206 is then:

a=π*D²/4=3.14*(70*10⁻⁹)²/4=3.85*10⁻¹⁵ m²

Assume that the pore 206 cross-section area covers half of the total available area of the scaffolding 204. The number of pores 206 equals approximately:

N=0.5*(10⁻³)²/3.85*10⁻¹⁵=130*10⁶

The circumference of the dielectric 212 at the center thickness (diameter 40 nm) is:

b=π*D=3.14*40*10⁻⁹=126*10⁻⁹ m

The total capacitor electrode area is:

A=N*b*h=130*10⁶*126*10⁻⁹*10⁻³=16.4⁻³ m²

The capacity of a parallel-plate capacitor is:

C=εₒ*εᵣ*A/d where: εₒ=1(36*π*10⁹)

Where d is the dielectric 212 thickness in meters. C will be in Farads. Assume Al₂O₃ dielectric with εᵣ=7.

C=(1/(36*π*10⁹))*7*16.4*10⁻³/10*10⁻⁹=0.101*10⁻³F=100

10 nm thickness of Al₂O₃ will have insulation breakdown voltage of 8 V, and a working voltage of 4 V is assumed. Therefore, the specific capacity will be:

100*4/1³=400 VμF/mm³

Compare to 7 VμF/mm³ for Tantalum electrolytic capacitors and one skilled in the art will appreciate that superior capacitor can be realized. The insulation and terminals will reduce the specific capacitance as calculated above, by amount depending on the dimensions of the capacitor.

Low resistance and inductance are critical issues for a useful capacitor. Calculating the series resistance of the capacitor involves combining all the conductor 208 and plug 216 layers in parallel. Assuming the same example, and assuming that both conductor and plug are made of Copper:

$$\begin{matrix}R = ( 1.72 * {10}^{- 8} * L [ m ] / S [ {m}^{2} ] ) / N \\ = \sim ( 1.72 * {10}^{- 8} * {10}^{- 3} / ( π * {( 30 * {10}^{- 9} )}^{2} / 4 ) / 130 * {10}^{6} \\ = 18.7 * {10}^{- 5} Ω = 187 μΩ\end{matrix}$$

Such low resistance allows for fast energy charging and discharging, again a highly desirably capacitor quality.

Due to the linear flow of current in the capacitor, the inductance will be extremely low.

In another embodiment of the current invention, a method of manufacture of batteries and electrochemical capacitors is similar to the previous embodiment with some changes. The general construction will be the same, with the step of deposing dielectric 212 being replaced by steps of deposing layer of a anode 272, deposing layer of a solid electrolyte 274 and deposing layer of an cathode 276, as depicted in FIG. 11, all preferably deposited by ALD technology. The layers may be depose in the reverse order to achieve similar performance.

The cathode 276 is ALD deposited, by way of example but not limitation, from: LiFePO₄, LiCoO₂, LiMn₂O₄, LiNiO₂, LiMPO₄, where M stands for a metal such as Fe, Co, Mn, Ti, etc., LiFe_{0.95}V_{0.05}PO₄ or A₂FePO₄ where A=Na, Li.

The solid electrolyte 274 is ALD deposited, by way of example but not limitation, from: Lithium Phosphorous Oxynitride (Lipon), Lithium Lanthanum Titanate (LLT), Beta-alumina complexed with a mobile ions such as Na⁺, K⁺, Li⁺, Ag⁺, H⁺, Pb²⁺, Sr²⁺ or Ba²⁺, non-stoichiometric Sodium Aluminate, Yttria-stabilized zirconia (YSZ) or (Li,La)ₓTi_{y}O_{z}, to name a few. The capacity of the ALD process to generate defect free and pinhole free layer is important in the deposition of the solid electrolyte to prevent internal shorts between the anode and cathode.

The anode 272 is ALD deposited, by way of example but not limitation from: Li₄Ti₁₅O₁₂, Ge(Li_{4.4}Ge), Si(Li_{4.4}Ge), Lithium-Titanate or Lithium Vanadium Oxide.

To keep the electrical separation between cathode and anode on a macroscopic level, the insulation 232 should be installed before or after the solid electrolyte is deposed.

Due to the structure, ions do not have to transport a distance 278 longer then tens or hundreds of nanometers during charge and discharge, thereby reducing the series resistance and charge and discharge time constants.

In operation, the electrical current flows in a battery or electrochemical capacitor from the outside electrical wiring to terminal 228, to filler 224, to the conductor 208 and from there to the anode 272. From the anode 272 to the cathode 276, the current will be carried by ions trough the ion transport distance 278, penetrating the solid electrolyte 274. From the cathode 276 the current will travel to the outside wiring via the plug 216, filler 240 and terminal 244. Somewhat different series are possible if the cathode 276 is deposited adjacent the conductor 208 and the anode 272 adjacent the plug 216. In addition, the current flows in the reverse during the charge-discharge cycle. The series resistance of the battery then is composed of mainly the ohmic resistance of conductor 208, plug 216 and the ion transport resistance. The ion transport distance is small, on the order of few tens of nanometers, resulting in small resistance.

In an alternative embodiments, conductor 208 and plug 216 may be omitted, relying on the anode 272 and cathode 276 to conduct the electrical current along the pore length. In such an embodiment the electrical resistance of anode 272 and cathode 276 should be adequate for the final product.

Due to the enormous aspect ratio of the pores, 14,000:1 in the example above and possibly 100,000:1, the current ALD equipment and method of deposition where the precursors are pulsed into the process chamber for a short time may not be adequate. It may be desirable to have a long dwell time of each precursor in the chamber to allow the molecules time to reach the farther away surface inside the pores, and long purge time between precursors to remove most of the molecules from the pores before letting-in the next precursor. Inert gas may be used between precursors to aid in purging, again requiring long dwell time and long pumping. To avoid wasting too much precursors, the reaction chamber may be separated from the vacuum pump during the long dwell times.

The method of depositing is achieved then by first pumping down the process chamber to adequate vacuum, and then shutting a valve between the process chamber and the vacuum pump. A chemical dose of the first precursor is then released into the process chamber. The amount in the dose should be sufficient to coat the pores 206 and all exposed surfaces in the chamber with some to spare. The valve is then open and the left-over precursor and the reaction remainders are pumped down. A purge gas is then made to flow into the reaction chamber. During this step, the vacuum pump may be disconnected to allow longer dwell time of the purge gas, but this is not a must as the purge gas may be inexpensive and not a problem to the environment. The process continues with the second precursor being handled in a similar fashion as the first precursor.

The production process involved hundreds or thousands of molecular or atomic layers deposited by ALD technology, depending on the required parameters of the final product. Each cycle of layer deposition is longer then in other ALD processes. This is not a cost issue, since due to the deep and full penetration of the ALD process, thousands or millions of components can share one large process chamber, with a total volume that can be more than a meter cubed.

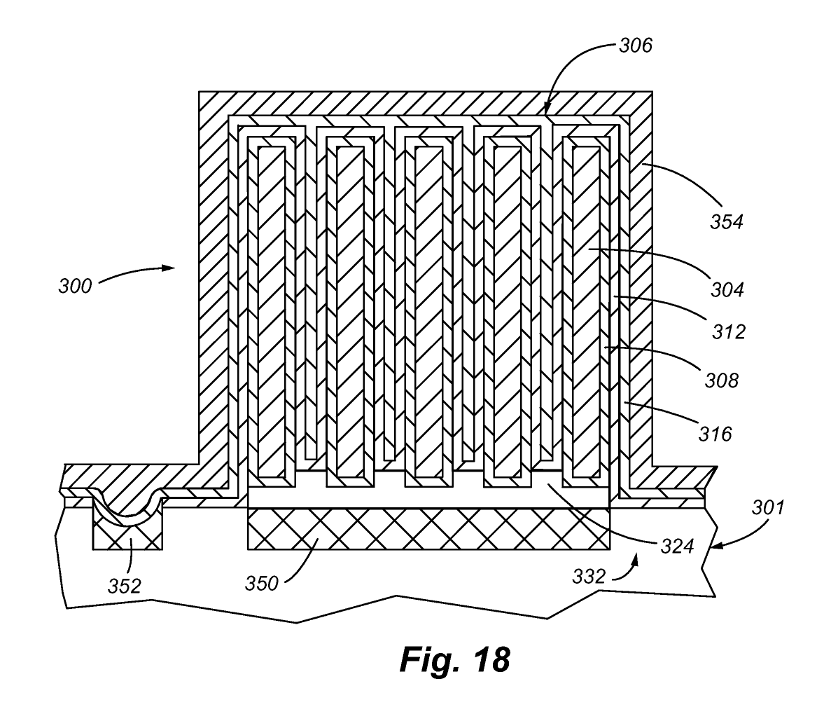

With reference now to FIGS. 18-20, alternative capacitor, electrochemical capacitor and/or battery constructions and methods of manufacturing the same will be described in accordance with at least some embodiments of the present invention. Similar to FIGS. 1-17, FIGS. 18-20 are not necessarily drawn to scale in an effort to facilitate a better and more clear understanding of the present disclosure.

Referring initially to FIG. 18, an exemplary capacitor 300 is depicted as being constructed on a carrier 301. The carrier 301 is a part of semiconductor chip, chip carrier, ceramic hybrid, Multi Chip Module (“MCM”), PCB and the like. Carrier 301 is made of insulating material 332 on part of its surface. A scaffolding 304 is provided to the required dimensions. The scaffolding 304 is coated with the first conductor 308 and then attached to the carrier 301, for example by brazing with filler material 324. The first conductive area 350 may correspond to an electrical contact pad or any other point of electrical connectivity on carrier 301.

While only one capacitor 300 is depicted in FIG. 18, one skilled in the art will appreciate that a single carrier 301 may have one or multiple capacitors 300 constructed thereon according to a manufacturing process described herein. Moreover, multiple capacitors 300 can be attached to the carrier 301 simultaneously.

In an alternative embodiment, the scaffolding 304 may be first attached to the carrier 301 and then conductor 308 is deposited. If scaffolding 304 is made of a material that does not readily wet the filler 324, the scaffolding 304 may be coated first on its bottom facet that is intended to be brazed with metal or any conductive material that will wet the filler 324.

Once the scaffolding 304 has been attached to the carrier 301, the manufacture of the capacitor 300 continues with the deposition of the dielectric 312. In some embodiments, the dielectric 312 is deposited over the entirety of the carrier 301, including the scaffolding 304 and areas without scaffolding 304. In locations where a second conducting area 352 is exposed (i.e., because it is not covered by the scaffolding 304), the dielectric 312 is generally not desirable. Accordingly, in some embodiments, the dielectric 312 which was deposited on the second conducting area 352 is one of mechanically grounded, etched away or removed by laser ablation. In some embodiments, it may prove more effective to utilize laser to remove the unwanted dielectric 312 since the carrier 301 with scaffoldings 304 together define a surface that is far from planar. In some embodiment, a material that prevent the deposition of dielectric 312 is placed on the second conducting area before deposition of dielectric 312 and removed after dielectric 312 is deposed.

The function of the insulator 232 (in FIG. 9-17) can now be performed by the insulation material 332 of the carrier 301. That is to say, a separate insulator is not necessarily required when the capacitor 300 is connected directly to the carrier 301. This is possible since the electrodes are not accessible and are protected in further steps.

Once the dielectric 312 has been removed from areas where it is not wanted, the plug 316 is deposited. In some embodiments, the plug 316 is fashioned to fully fill the pores 306. Alternatively, a final step of CVD, evaporation coating or sputtering is used to finally fill or seal the pores 306. In addition to covering the scaffolding 304, the plug 316 also covers the dielectric 312 on the carrier 301 as well as the exposed second conducting area 352. Since the plug 316 operates as the second electrode of the capacitor 300, a capacitor 300 is established from the first conducting area 350 to the second conducting area 352.

A top layer of material 354 is then deposited using CVD, sputtering, electroless deposition, electroplating, or by any other mechanism that is known to deposit a relatively thick layer of material. This is done to ensure that the connection between the plug 316 and the second conducting area 352 is secure and has a relatively low resistance. In some embodiments, selective deposition can be done by, for example, electroplating, while some areas are protected with an un-conductive layer.

In some embodiments, the scaffolding 304 can be produced in-situ on the carrier 301 by depositing Aluminum over the carrier 301, removing the Aluminum from the unwanted areas, and anodizing the Aluminum until the pores 306 reach the conductive material 350. Details of this process are described in U.S. Pat. No. 6,838,297 to Iwasaki et al., the entire contents of which are hereby incorporated herein by reference.

In another embodiment, similar to the discussions above, electrochemical capacitors and batteries are constructed by replacing the step of depositing dielectric 312 with several steps of depositing, by ALD, cathode 276, solid electrolyte 274 and anode 272, in that or the reversed order, as depicted in FIG. 11.

In another embodiment, similar to the previous embodiment, the steps of depositing conductor 308 and plug 316 are omitted, and the cathode and anode carry the electrical current along the length of the pore 306.

The apparatus obtained from the above-described method is an on-module-type electrical element. In some embodiments, a capacitor having the depicted scaffolding 304, pores 306, layers of conductor 308, dielectric 312, and the like is created. The on-module capacitor can be easily handed by the carrier 301 and mass fabrication of such on-module capacitors on a common carrier is easily obtained. In some embodiments, on-module electrochemical capacitors and batteries are created that include a cathode and anode layer as opposed to the dielectric layer 312 of the capacitor. Multiple on-module electrochemical capacitors and batteries can be produced on a single carrier 301, thereby facilitating the efficient creation of multiple electrical elements.

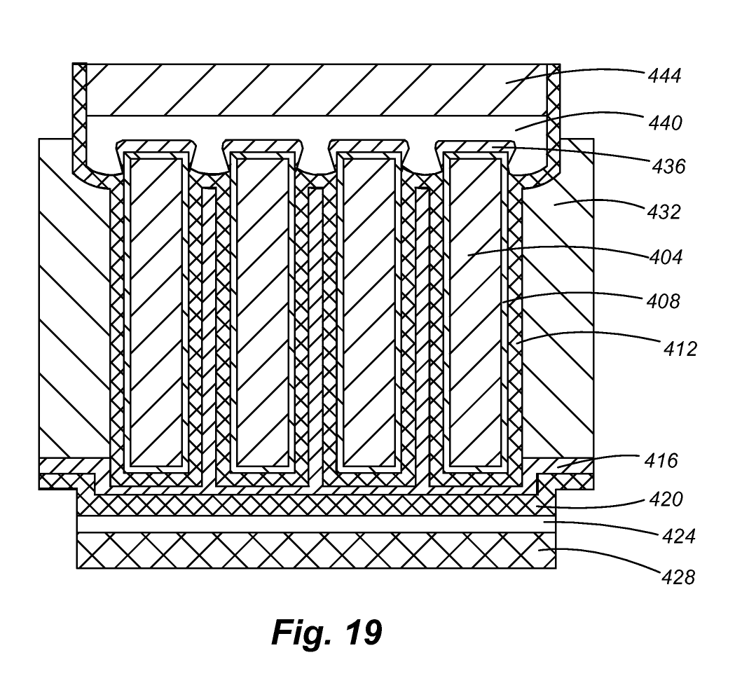

Referring now to FIG. 19, another exemplary capacitor, battery, or electrochemical capacitor 400 is depicted in accordance with embodiments of the present invention. In particular, an anodized nanopore capacitor 400 with a non-metallic conductor 408 and plug 416 is depicted. The general dimensions of the capacitor, battery, or electrochemical capacitor 400 and its components are similar to one or both of the capacitors, battery, or electrochemical capacitor 100 and 200 and their components.

In the current ALD art, deposition of metals is in wide research, but it may take time to have available technologies to deposit metals inexpensively and at deep pores with an aspect ratio of substantially more then 1000:1. Research and deposition of TiN, TaN, WN and other nitrides and metal Silicides such as TiSi₂, PtSi, CoSi₂, NiSi, WSi₂, are commonly performed. Nitrides have substantially higher resistance then metals, approximately 10-1000 times higher. Metals have 1.7 to 10 μΩCm (1.7-10*10⁻⁸ Ωm) and as-deposited Nitrides have 100-1000 μΩCm. However, if properly designed, a nanopore capacitor, battery, or electrochemical capacitor 400 with nitride, silicide or other non-metal conductors 408 and plug 416 can achieve better resistance performance then existing electrolytic capacitors. Furthermore, a capacitor constructed with at least one nitride, silicide or other non-metal conductor and/or plug can be manufactured more easily and cost effectively than comparable capacitors having a different type of pure metal as the conductor plug. As one example, the ALD process for depositing nitride, silicide or other non-metal materials is somewhat easier to perform in the depth of the pores than the ALD process for depositing pure metals. To enable making the electrical contacts, there will be a need for metallic deposition, but only at the exposed surfaces and not in deep pores.

The capacitor, battery, or electrochemical capacitor 400 of FIG. 19 is depicted as having a scaffolding structure 404 with pores defined therein. The scaffolding is made of nanopore material as descried above, where at least one pore transverses the scaffolding from a first facet to a second facet.

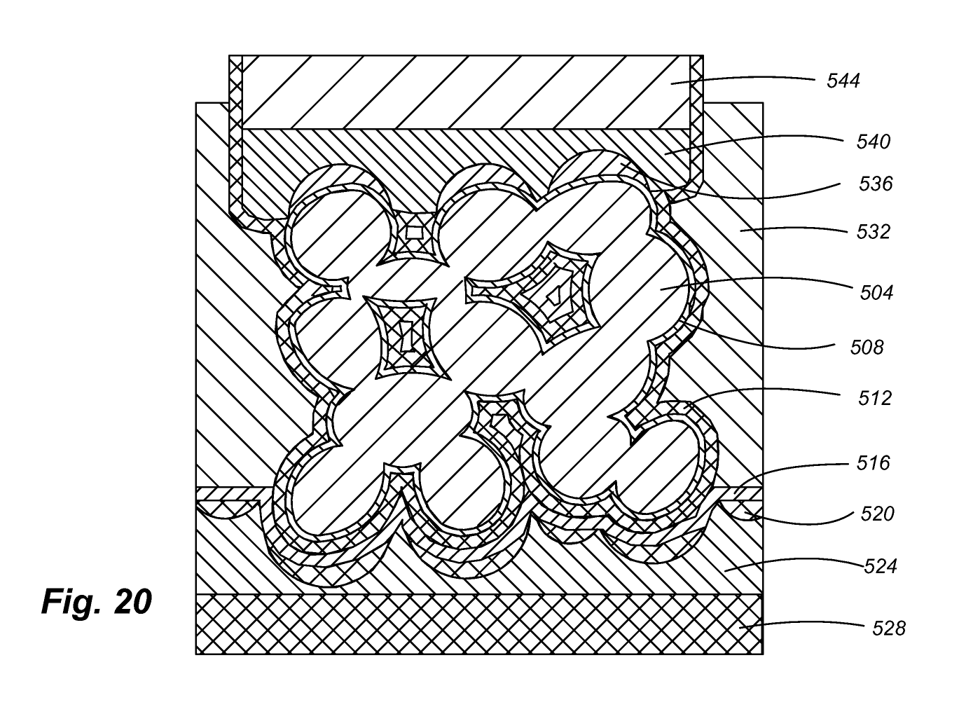

Another embodiment of the present invention, depicted in FIG. 20, contemplates the use of a sintered material for the scaffolding 504 of the capacitor, battery, or electrochemical capacitor 500. In some embodiments, sintered metals may be utilized as the sintered material for the scaffolding 504. Sintered stainless steel and sintered brass are commercially available for use as particulate filters with a pore size of around 500 nm, but can be made to have a smaller pore size. The use as particulate filter demonstrates that there are many pores that transverse the sintered material from a first facet to a second facet

The capacitor, battery, or electrochemical capacitor 500 includes a sintered material scaffolding 504 which is a macroscopic lump of material with microscopic pores therein. The pores are neither straight nor uniform, are intersecting and do not have a homogeneous diameter as in the scaffolding 404 of capacitor, battery, or electrochemical capacitor 400, but is still suitable for use as a capacitor, battery, or electrochemical capacitor. At least one pore transverses the scaffolding from a first facet to a second facet.

The dimensions of the capacitor, battery, or electrochemical capacitor 400, 500 and its components are similar to the dimensions of the capacitor(s) depicted in FIGS. 1-17.

In some embodiments, the sintered material scaffolding 504 can be used as the conductor, to save one step of ALD deposition. However, a good, un-oxidized surface should be maintained for most of the sintered material scaffolding 504. By using the sintered material 504 as scaffolding only and not using its conducting capability, a capacitor, battery, or electrochemical capacitor can be manufactured with similar performance to an anodized Aluminum scaffolding-type capacitor 400. The only difference between the capacitors 400 and 500 would be that the pores are not straight and aligned, but rather interconnected in the capacitor 500 having a sintered material scaffolding 504.

In the embodiments depicted in FIGS. 19 and 20, a layer of conductor 408, 508 is deposited on the whole surface of the scaffolding 404, 504. Exemplary types of materials which may be used for the conductor 408, 508 include, without limitation, TiN, TaN, WN, TiSi₂, PtSi, CoSi₂, NiSi and WSi₂. Conductor 408, 508 act as the first electrode of the capacitor and as an electric conductor conveying electric current to the capacitor, battery or electrochemical capacitor structure.

On a first facet of the structure there is a top contact 436, 536, produced by deposition of metal, several metallic layers, composites or any material that have good adherence and electrical contact to the conductor 408, 508, that have reasonable electrical conductance and that will wet metals readily for further steps, with no or very shallow penetration into the pores of the scaffolding 404, 504 as discussed above.

A top terminal 444, 544 is brazed to the top contact 436, 536 with a top filler material 440, 540.

A dielectric layer 412, 512, is deposited on the whole surface of the conductor 408, 508.

A plug 416, 516 is deposited on the whole surface of the dielectric 412, 512. In some embodiments, the material used to construct the plug 416, 516 is similar or identical to the material used to construct the conductor 408, 508. Also in some embodiments, the plug 416, 516 may or may not entirely fill the pores of the scaffolding 404, 504. The plug is performing the function of the second electrode of the capacitor and as an electric conductor conveying electric current to the capacitor, battery or electrochemical capacitor structure.

On a second facet (opposite the top facet) of the scaffolding 404, 504, a bottom contact layer 420, 520 made of a material similar or the same as top contact 436, 536 is deposited onto the plug 416, 516, similar to the top contact 436, 536. A bottom terminal 428, 528 is brazed to the bottom contact layer 420, 520 with a bottom filler material 424, 524.

Around the scaffolding 404, 504 an insulator 432, 532 is provided in such a way that it macroscopically separates any conductive material which is in electrical contact with conductor 408, 508 from any conductive material which is in electrical contact with plug 416, 516.

In another embodiment of this invention, an electrochemical capacitor or a battery is constructed similar to the previous embodiment, but with the dialectic 412, 412 replaced with layers of anode 272, solid electrolyte 274 and cathode 276 as depicted in FIG. 11. FIG. 11 depicts part of a pore in scaffolding 404 or 504. It should be noted that lines depicted with respect to the scaffolding 404, 504 and the various other layers around it may or may not necessarily be straight, but the thickness of such layers is uniform.

In another embodiment of this invention, an electrochemical capacitor or a battery is constructed similar to the previous embodiment, but without the conductor 208 and plug 216, relying on the cathode 276 and anode 272 to carry the electrical current along the pore length.

In the case of electrochemical capacitor or a battery, the insulator 432, 532 is separating between anode 272 and cathode 276. The location of anode 272 and cathode 276 may be reversed with similar performance.

Another embodiment of the current invention is the method of manufacturing capacitor 400, 500:

a. Making the scaffolding 404, 504, in one embodiment by anodizing aluminum to create nanopore Al₂O₃. In another embodiment by sintering a powder, preferably metal powder. The conductivity of the metal powder does not significantly affect the electric performance. The scaffolding should have a plurality of pores, where at least one pore transverses the scaffolding from a first facet to a second facet.

b. Coating the scaffolding 404, 504 by ALD process with the conductor layer 408, 508, made of TiN, TaN, WN, TiSi₂, PtSi, CoSi₂, NiSi, WSi₂ or any other material with reasonably good conductivity, on the order of 1000 μΩCm or better. The conductor material can be annealed after deposition to improve conductivity. The ALD process that is used to deposit the conductor should enable very deep penetration into pores with aspect ratio of 10,000:1 or more. Long dwell time of each precursor dose is desirable to enable full penetration, but this is not a cost issue due to the possibility of mass deposition in a very large chamber. At least one end of the scaffolding where the pores end in scaffolding 404 or in any end in scaffolding 504 is coated as well.

c. Deposition of the top contact material 436, 536. This is preferably a metal that will have good wetting of other metals. It is deposited by CVD, sputtering, evaporating, or any other deposition process that can produce a layer of the top contact 436, 536 on a first facet of the scaffolding 404, 504 with minimal penetration into pores. ALD can be used as well if it is specifically designed to have low penetration. Having some metal deposited on any other outside surface area is not needed but will not cause a problem. Many metals are possible, including Nickel, Chromium, Zinc, Gold, Tungsten, Ruthenium, Palladium, Silver, metal compositions, layered metals etc. The requirements are reasonably high melting temperature to avoid melting in subsequent steps and slow oxidation, to minimize the need for inert atmosphere between steps. It is acceptable if some or all of the pores will be fully plugged at the first face by the top contact 436, 536. The top contact 436, 536 may be flushed with a thin layer of noble metal to prevent oxidation until the next step.

d. Brazing the top terminal 444, 544 to the top contact 436, 536. A filler material 440, 540 is used as in common brazing art. Since the top contact 436, 536 does not penetrate deep into the pores, there is little risk of filler material 440, 540 running into and filling the pores, especially if conductor 408, 508 does not have good wetting of filler 440, 540. In some embodiments, the top terminal 444, 544 is bulk metal such as copper or copper alloy, and the top filler 440, 540 is a brazing filler having a selected melting temperature. The top terminal 444, 544 may be made of several layers of metals, with the outer layer ready for soldering into a PCB and preferably designed to act as a solder barrier. The top terminal 444, 544 can be made from a metal alloy that has a similar thermal coefficient of expansion as the rest of the structure, to minimize stress, or it can be soft enough to accept thermal stress without damage to the structure. The thickness of the filler should be sufficient to absorb the flatness difference between the top terminal 444, 544 and the end of the scaffolding 404, 504. It is preferred to braze without flux to avoid the need for cleaning, and therefore the top contact 436, 536 and the filler 440, 540 should be fairly free of oxidation. Inert atmosphere may be used between steps to prevent oxidation. In addition, a thin layer of noble metal may be covering the filler 440, 540 before the brazing step.

e. Deposition of the dielectric 412, 512, that can be one of many available, such as Al₂O₃, Ta₂O₅, other metal oxides, Si₃N₄, layers of different materials or mixture of materials as discussed before. Very deep penetration of insulating materials by ALD process, especially Al₂O₃, is a known art. ALD produces high quality deposited layers, with no pinholes, defects etc. The deposition process can be designed to create an amorphous structure and not crystalline structure to improve the insulation quality. A defect free and pinhole free layer throughout the inner surface of the pores is important. Again, long dwell time of each precursor dose is desirable to achieve full penetration to the whole depth of pores.

f. Placing the insulator 432, 532, on all the side surfaces of the scaffolding 404, 504, by re-flow or cast of glass or plastic material. Glass should be made from a composition that have fairly similar thermal coefficient of expansion to the combined coefficient of the rest of the structure, so that stress over the size of the whole construction is not excessive. Plastic will be able to take the stress even with large difference in expansion coefficient. Plastic should be selected to have low out-gassing so as to not damage subsequent steps. The insulator is very important to the usefulness of the final assembly, since without it there will be a difficulty of using the assembly by soldering wires to it or soldering it directly to a Printed Circuit Board due to the nanometer scale separation of the electrodes. Note that this step f may be performed before step e without significant change in the performance. In another embodiment, a thin layer of glass and a layer of plastic or other mixed constructions can be used as well. The glass layer can be on the order of one to few tens of microns thick, and deposited in this step f, while the plastic layer of few hundreds of microns will be placed later in the process after the plug material is removed from the surface of the glass. This way the need to place any plastic material in the ALD deposition chamber is avoided.

g. Deposition of the plug 416, 516 by ALD. The plug 416, 516 is made of a conducting material either the same as the conductor 408, 508 or different material with similar characteristics. To have similar conductivity as the conductor 408, 508, the plug 416, 516 can include a thicker layer since the diameter is smaller. It is preferred that the plug 416, 516 will fill up the pore, but it is not a requirement. Again, as in the deposition of the conductor 408, 508, the plug 416, 516 deposition process should facilitate deep penetration into the pores.

h. Deposition of the bottom contact material 420, 520 on a second facet of the assembly. This is a metal similar to the top contact 436, 536, and may be the same or a different metal. It is deposited by ALD, CVD, sputtering, evaporating, or any other deposition process that can produce a layer of the metal on one side of the scaffolding. The bottom contact 420, 520 may plug the opening of any pore that was not filled by the plug 416, 516.

i. Brazing the bottom terminal 428, 528 with the bottom filler 424, 524 to the bottom contact 420, 520, finally making sure that all pores that are not filled-up are sealed to prevent environmental materials from entering the pores. The bottom terminal 428, 528 may be the same material as the top terminal 444, 544, but the bottom filler 424, 524 should have a lower melting temperature than the top filler 440, 540. This step is preferably performed in vacuum or in a selected atmosphere to control what is trapped in any open pore that is finally plugged.

j. Separating the individual capacitors 400, 500 if steps b-i were shared among many capacitors in an array. Removing, mechanically or chemically, all unwanted dielectric, plug and bottom contact that are exposed on surfaces and are not wanted.

It should be noted that the top terminal and bottom terminal may be deposited on the top and bottom contacts directly by technologies that are capable of making thick layers of metal, such as electrochemical deposition or electroless deposition. Since such thick depositions technologies are made in liquid, if the top terminal is deposited this way, the electrolyte should be thoroughly removed from the pores before further steps. If the bottom terminal is deposited in such a way, the pores must be totally filled by the plug or fully plugged by the bottom contact to avoid any liquid being trapped in the pores. Alternatively, if the the top contact 436, 536 and bottom contact 420, 520 are deposited in such a way that all pores are hermetically sealed, then terminals 428, 444, 528 and 544 can be deposited together before step j in a liquid environment directly.

It should also be noted that diffusion-barrier layers may be deposited to prevent diffusion of materials from layer to layer. Some diffusion may be unavoidable or even desirable, for example between the contact layers and the filler material.

Seed layers may be used to enable good adhesion of the contact layers materials to the conductor and plug. For example, a metallic seed layer may be deposited by ALD or CVD on the conductor or plug, and a contact is then deposited by sputtering or evaporation on the seed layer.

Also, an oxidation preventing layer may be deposited onto the top contact and the bottom contact, for example a thin layer of evaporated Gold, to prevent oxidation. This layer may diffuse into the filler material during brazing.

In addition, solder barrier similar to solder barrier 130 in FIG. 1 may be applied to improve assembly process onto PCB and the like, or alternatively it may be a part of the electrodes before brazing.

Another embodiment of this invention is the method of manufacture of a battery or an electrochemical capacitor. In this embodiment step e. of the previous embodiment which consist of depositing the dielectric layer and step f of installing the insulator are replaced by the following steps:

m. Depositing anode 272 as depicted in FIG. 11, from materials discussed above for anode material.

n. Depositing solid electrolyte 274 as depicted in FIG. 11, from materials discussed above for solid electrolytes.

o. Placing the insulation 432, 532. This step may be performed before step n with similar product performance.

p. Depositing cathode 276 as depicted in FIG. 11, from materials discussed above for cathode material. Note that this step and step m. can be swapped with similar product performance.

In another embodiment, an electrochemical capacitor or a battery is manufactured without deposing the conductor 408, 508 and plug 416, 516, and where the anode 272 and cathode 274 are fulfilling the function of conducting current along the pores length in addition to the battery electrode function.

Low leakage current is a critical issue for a useful capacitor, battery or an electrochemical capacitor. Such leakage current is limited by utilizing an ALD deposition process to deposit the dielectric 412, 512 in case of capacitor or the solid electrolyte 274 in the case of battery or electrochemical capacitor. ALD is known to achieve very conformal coating free of pores or defects, and which allows for good quality layer with low number of molecular layers.

There are other benefits of the current design of capacitors compared to electrolytic capacitors, such as better reliability, wide range of working temperature, long life, bipolar operation, non-contaminating if failed, better capacitance accuracy, better temperature stability of parameters, tolerance to voltage spikes etc. Benefits to electrochemical capacitors and batteries include short ion transport length, fast charge and discharge etc.

Low series resistance is also of great concern for a useful capacitor, battery or an electrochemical capacitor. Calculating the series resistance of the capacitor involves combining conductor and plug layers in parallel. Assuming, by way of example but not limitation, that a capacitor was made from a 1×1×1 mm³ nanopored Al₂O₃, with average pore diameter of 70 nm and 130*10⁶ pores. The conductor layer is 6 nm thick, the insulation layer is 10 nm thick, and the plug diameter is nominally 38 nm, that is deposition of 19 nm thick layer. The capacitance as calculated in the earlier embodiment example is 100 μF. Assuming further that the conductor and plug are made of TiN with 1000 μΩCm, or 10⁻⁵ Ωm, which is achievable resistance for as deposited layer, and could be improved substantially by annealing or other techniques. To ease the calculation, it can be assumed that the tube of conductor has a thickness of 6 nm and mean diameter of 67 nm and also has about the same cross section area as the plug at 38 nm diameter. The resistance is:

$$\begin{matrix}R = ( {10}^{- 5} * L [ m ] / S [ {m}^{2} ] ) / N \\ = ( {10}^{- 5} * {10}^{- 3} / ( π * {( 38 * {10}^{- 9} )}^{2} / 4 ) ) / 130 * {10}^{6} \\ = 7 * {10}^{- 2} Ω = 70 m Ω\end{matrix}$$

A Tantalum electrolytic capacitor with 100 μF capacitance is known to have 0.9-1.5 Ω series resistance. Accordingly, for excellent performance that improves over the performance of the currently available electrolytic capacitors, the use of poorly conducting material for the conductor and plug is sufficient.

The inductance will be very low due to the almost linear flow of the electrical current and the impedance is expected to stay the same up to very high frequencies, similar to multi-layer ceramic capacitors. Therefore, in contrast to current practice of placing a ceramic capacitor next to each electrolytic capacitor, such practice is not needed with capacitor 400, 500.

For electrochemical capacitor or battery, the short ion transport distance 278 of ions in the electrolyte as shown in FIG. 11, is basically a radial travel in a pore for a distance of few tens of nanometers. The time the ions need to travel from anode to cathode and back is reduced, and there is also reduction of series resistance and increase the maximum allowable currents of charge/discharge compared to conventional electrochemical capacitors or batteries.

It should be appreciated that variations on the structural assembly are possible. For example, in another embodiment, a top contact is deposited on one face of the scaffolding directly, for example by sputtering. Next, the top terminal is brazed to this top contact. Then a conductor is ALD deposited, and an dielectric is ALD deposited. Then the insulator is installed and then the plug is ALD deposited. Finally the bottom contact is deposited similar to the top contact and the bottom terminal is brazed. Another variation is as follows: a top contact is deposited on one face of the scaffolding directly, for example by sputtering. Next, the top terminal is brazed to this top contact. Then a conductor is ALD deposited. Then the insulator is installed and an dielectric is ALD deposited and then the plug is ALD deposited. Finally the bottom contact is deposited and the bottom terminal is brazed.

In another embodiment, an anodized nanopore scaffolding is made on an Aluminum structure that have a layer of different metal that stops the anodizing process and leave the pores end directly at the different metal. If the different metal is not oxidized by the electrolyte, after drying the scaffolding has already built-in top terminal. Then a conductor is ALD deposited, and a dielectric is ALD deposited. Then the insulator in installed and then the plug is ALD deposited. Finally the bottom contact is deposited and the bottom terminal is brazed.

The foregoing discussion has been presented for purposes of illustration and description. The foregoing is not intended to limit the invention to the form or forms disclosed herein. In the foregoing Detailed Description for example, various features of the invention are grouped together in one or more embodiments for the purpose of streamlining the invention. This method of invention is not to be interpreted as reflecting an intention that the claimed invention requires more features than are expressly recited in each claim. Rather, as the following claims reflect, inventive aspects lie in less than all features of a single foregoing disclosed embodiment. Thus, the following claims are hereby incorporated into this Detailed Description, with each claim standing on its own as a separate preferred embodiment of the invention.

While various embodiments of the present invention have been described in detail, it is apparent that modifications and adaptations of those embodiments will occur to those skilled in the art. However, it is to be expressly understood that such modifications and adaptations are within the spirit and scope of the present invention, as set forth in the following claims.

1-54. (canceled)

55. A method of manufacturing an electrical component, the method comprising:
providing a porous scaffolding formed having a network of irregular shaped pores defined by internal surfaces of the scaffolding, with at least one pore having first and second openings on first and second external surface regions of the scaffolding respectively;
forming a plurality of contiguous conformal layers on at least a portion of the internal surface of the at least one pore;
providing a first electrical contact to at least one of the scaffolding and a first of the plurality of conformal layers at the first opening;
providing a second electrical contact to a second of the plurality of conformal layers at the second opening; and
depositing an insulating material that electrically insulates the first contact from the second contact.

56. A method according to claim 55 and comprising forming at least one of the conformal layers by atomic layer deposition (ALD).

57. A method according to claim 55 and comprising depositing the insulating material prior to forming the second of the plurality of conformal layers.

58. A method according to claim 55 wherein the first layer comprises a dielectric material conformally formed directly on the at least a portion of the internal surface.

59. A method according to claim 58 wherein the second layer comprises a conducting material formed conformally to the first layer.

60. A method according to claim 55 wherein the plurality of layers comprises three layers.

61. A method according to claim 60 wherein the first and second layers comprise a conducting material and sandwich between them a third layer formed from an dielectric material.

62. A method according to claim 60 wherein the first and second layers comprise an anode and cathode respectively and sandwich between them a third layer formed from an electrolyte.

63. An electrical component, comprising:
a scaffolding formed having a network of irregular shaped pores defined by internal surfaces of the scaffolding, with at least one pore having first and second openings on first and second external surface regions of the scaffolding respectively;
a plurality of contiguous conformal layers on at least a portion of the internal surface of the at least one pore;
a first electrical contact to at least one of the scaffolding and a first of the plurality of conformal layers at the first opening;
a second electrical contact to a second of the plurality of conformal layers at the second opening; and
an insulating material that electrically insulates the first contact from the second contact.

64. An electrical component according to claim 63 wherein the first layer comprises a dielectric material formed directly on the at least a portion of the internal surface, and the second layer comprises a conducting material formed conformal to the first layer.

65. An electrical component according to claim 63 wherein the plurality of layers comprises three layers.

66. An electrical component according to claim 65 wherein the first and second layers comprise an anode and cathode respectively, and sandwich between them a third layer formed from an electrolyte.

67. An electrical component according to claim 65 wherein the first and second layers comprise a conducting material and sandwich between them a layer formed from a dielectric.
